(19) United States
(12) Patent Application Publication
(10) Pub. No.: US 2021/0288650 A1
(43) Pub. Date: Sep. 16, 2021

(54) SEMICONDUCTOR DEVICE AND CIRCUIT LAYOUT METHOD

(71) Applicant: Preferred Networks, Inc., Tokyo (JP)

(72) Inventors: Tanvir AHMED, Tokyo (JP); Ken NAMURA, Tokyo (JP)

(21) Appl. No.: 17/199,587

(22) Filed: Mar. 12, 2021

(30) Foreign Application Priority Data
Mar. 16, 2020 (JP) 2020-045750

(51) Int. Cl. H03K 19/1776; H01L 27/118; G06F 13/16; G06F 13/12

(52) U.S. Cl. CPC H03K 19/1776; G06F 13/12; G06F 13/1668; H01L 27/11803

(57) ABSTRACT

A semiconductor device includes multiple reconfiguration blocks arranged in a first direction, logic of the multiple reconfiguration blocks being reconfigurable, multiple non-reconfiguration blocks disposed between the multiple reconfiguration blocks, each of the multiple non-reconfiguration blocks including multiple first arithmetic units, and logic of the multiple first arithmetic units being not reconfigurable, and multiple processing units implemented in the multiple reconfiguration blocks and the multiple non-reconfiguration blocks in a matrix form, the multiple processing units including second arithmetic units. For each of multiple processing rows, the second arithmetic units are implemented using either the first arithmetic units of a corresponding one of the non-reconfiguration blocks or a corresponding one of the reconfiguration blocks, each of the multiple processing rows being a row in which a predetermined number of processing units among the multiple processing units are arranged in a second direction crossing the first direction.

### CROSS-REFERENCE TO RELATED APPLICATIONS

This application is based upon and claims priority to Japanese Patent Application No. 2020-045750 filed on Mar. 16, 2020, the entire contents of which are incorporated herein by reference.

### BACKGROUND

### 1. Technical Field

The disclosure herein relates to a semiconductor device and a circuit layout method.

### 2. Description of the Related Art

In field-programmable gate arrays (FPGAs) that are logically reconfigurable, the number of gates increases as semiconductor manufacturing technology advances. FPGAs with hardware functions, such as a central processing unit (CPU) and a memory, are also developed. For example, a method of efficiently performing machine learning by implementing cascaded digital signal processors (DSPs) and a memory in an FPGA has been proposed.

In order to efficiently perform machine learning such as deep learning, many matrix multiplications may be performed in parallel by using a systolic array including multiple processing elements arranged in a matrix. For example, when a systolic array is implemented in an FPGA with a hardware multiplier, the hardware multiplier can be used as a multiplier in a processing element. However, the number of the hardware multipliers in an FPGA is limited. In addition, in order to perform matrix multiplications faster in a systolic array implemented in an FPGA, it is necessary to reduce the length of interconnects connecting processing elements in the FPGA.

Embodiments of the present disclosure have been made in view of the above-described points, and it is desirable to improve the implementation efficiency of multiple processing units including arithmetic units and logic circuits in the semiconductor device and improve the performance of the semiconductor device.

### SUMMARY

According to one aspect of the present disclosure, a semiconductor device includes multiple reconfiguration blocks arranged in a first direction, logic of the multiple reconfiguration blocks being reconfigurable, multiple non-reconfiguration blocks disposed between the multiple reconfiguration blocks, each of the multiple non-reconfiguration blocks including multiple first arithmetic units, and logic of the multiple first arithmetic units being not reconfigurable, and multiple processing units implemented in the multiple reconfiguration blocks and the multiple non-reconfiguration blocks in a form of a matrix, the multiple processing units including second arithmetic units, wherein, for each of multiple processing rows, the second arithmetic units are implemented using either the first arithmetic units of a corresponding one of the non-reconfiguration blocks or a corresponding one of the reconfiguration blocks, each of the multiple processing rows being a row in which a predetermined number of processing units among the multiple processing units are arranged in a second direction crossing the first direction.

According to one aspect of the present disclosure, the implementation efficiency of multiple processing units including arithmetic units and logic circuits in the semiconductor device can be improved, thereby improving the performance of the semiconductor device.

### BRIEF DESCRIPTION OF THE DRAWINGS

FIG. 1 is a block diagram illustrating an example of a semiconductor device according to an embodiment of the present disclosure;

FIG. 2 is a block diagram illustrating an example of a systolic array implemented in the semiconductor device of FIG. 1;

FIG. 3 is a block diagram illustrating an example of the processing element of FIG. 2;

FIG. 4 is a block diagram illustrating an example of the accumulator of FIG. 2;

FIG. 5 is an explanatory diagram illustrating an example of the systolic array implemented in the semiconductor device of FIG. 1;

FIG. 6 is an explanatory diagram illustrating another example of the systolic array implemented in the semiconductor device of FIG. 1;

FIG. 7 is an explanatory diagram illustrating a block to which each element of the processing elements of FIG. 2 is implemented (or mapped);

FIG. 8 is an explanatory diagram illustrating a block to which each element of the accumulator of FIG. 2 is implemented (or mapped);

FIG. 9 is a flowchart for mapping the processing element of the systolic array to the semiconductor device of FIG. 1;

FIG. 10 is an explanatory diagram illustrating a relation between the number of lookup tables in the reconfiguration block of FIG. 1 and the number of lookup tables used by a processing element to be implemented in the reconfiguration block;

FIG. 11 is a flowchart illustrating an example of a process of step S200 of FIG. 9;

FIG. 12 is an explanatory diagram illustrating an example of mapping the processing elements to the reconfiguration block;

FIG. 13 is a block diagram illustrating an example (i.e., a comparative example) of implementing an array of processing elements including multipliers on an FPGA with lookup tables;

FIG. 14 is a block diagram illustrating an example (i.e., a comparative example) of implementing the systolic array in an FPGA in which a memory block, a reconfiguration block, and a hard functional block are repeatedly disposed;

FIG. 15 is a block diagram illustrating an example (i.e., a comparative example) of implementing the systolic array in the FPGA in which the memory block, the reconfiguration block, and the hard functional block are repeatedly disposed;

FIG. 16 is an explanatory diagram illustrating a problem caused when the processing elements are implemented in the semiconductor device by using an architecture illustrated in FIG. 14 or FIG. 15;

FIG. 17 is an explanatory diagram illustrating an example of an operating frequency used when the array or the systolic array is implemented by using each of the architectures illustrated in FIG. 5, FIG. 13, FIG. 14, and FIG. 15;

FIG. 18 is an explanatory diagram illustrating an example of the number of reconfiguration blocks used when the array or the systolic array is implemented by using each of the architectures illustrated in FIG. 5, FIG. 13, FIG. 14, and FIG. 15;

FIG. 19 is an explanatory diagram illustrating an example of the number of multipliers used when the array or the systolic array is implemented by using each of the architectures illustrated in FIG. 5, FIG. 13, FIG. 14, and FIG. 15;

FIG. 20 is an explanatory diagram illustrating an example of wall-clock time measured when the array or the systolic array is implemented by using each of the architectures illustrated in FIG. 5, FIG. 13, FIG. 14, and FIG. 15; and

FIG. 21 is a block diagram illustrating an example of a hardware configuration of an information processing device that maps the systolic array of FIG. 2 to the semiconductor device of FIG. 1.

### DETAILED DESCRIPTION

In the following, embodiments of the present disclosure will be described in detail with reference to the accompanying drawings. The arrow of the signal line indicates a direction in which the signal is transferred in the signal line. In order to simplify diagrams, multiple signal lines may be represented as a single signal line.

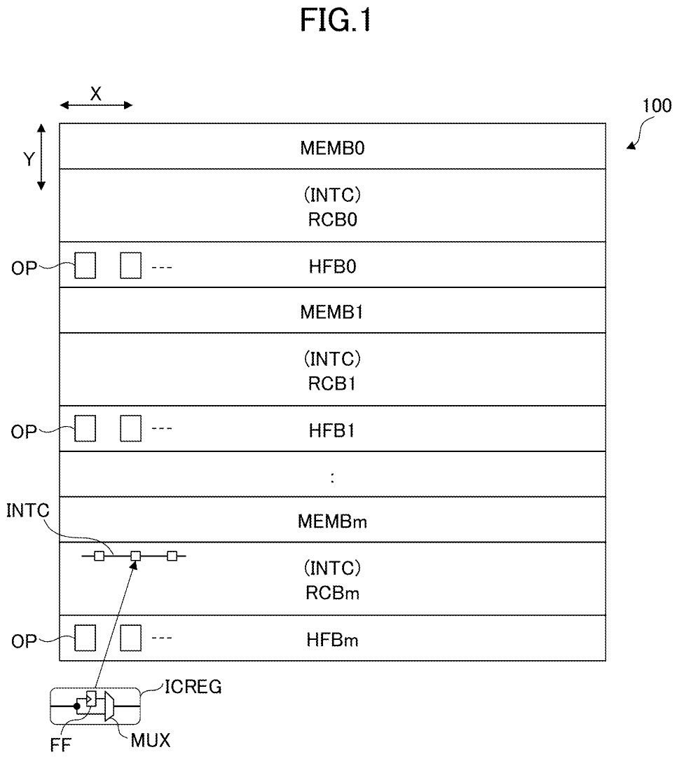

FIG. 1 is a block diagram illustrating an example of a semiconductor device according to an embodiment of the present disclosure. A semiconductor device 100 illustrated in FIG. 1 is, for example, an FPGA that can reconfigure logic. The semiconductor device 100 may have a block structure illustrated in FIG. 1 and may be a programmable device other than an FPGA as long as logic can be reconfigured.

The semiconductor device 100 may include a memory block MEMB (e.g., MEMB0, MEMB1, . . . , and MEMBm), a reconfiguration block RCB (e.g., RCB0, RCB1, . . . , and RCBm), and a hard functional block HFB (e.g., HFB0, HFB1, . . . , and HFBm) repeatedly arranged in a vertical direction Y of FIG. 1. The reconfiguration block RCB may be able to reconfigure logic. The hard functional block is an example of a non-reconfiguration block in which logic cannot be reconfigured.

Each of the reconfiguration blocks RCB except the reconfiguration block RCB0 may be disposed between the hard functional blocks HFB, and each of the hard functional blocks HFB except the hard functional block HFBm may be disposed between the reconfiguration blocks RCB. In the example illustrated in FIG. 1, the semiconductor device 100 includes m+1 memory blocks MEMB, m+1 reconfiguration blocks RCB, and m+1 hard functional blocks HFB (where m is an integer greater than or equal to 1).

The numbers (including m) added at the end of the memory block MEMB, the reconfiguration block RCB, and the hard functional block HFB are numbers to identify respective blocks. A value of m is greater than or equal to “1”. The memory block MEMB, the reconfiguration block RCB, and the hard functional block HFB each have an elongated rectangular shape extending in a horizontal direction X intersecting the vertical direction Y. The vertical direction Y is an example of a first direction and the horizontal direction X is an example of a second direction.

The memory block MEMB may include multiple memory units having a predetermined storage capacity (e.g., a capacity from a few kilobits to several tens of kilobits). For example, a static random access memory (SRAM) constitutes the memory unit and the memory units are disposed along the horizontal direction X of FIG. 1. In response to receiving an address, a write request, and write data, each of the memory units may store the write data in a storage area specified by the address. Additionally, in response to receiving an address and a read request, each of the memory units may output data stored in a storage area specified by the address as read data.

The reconfiguration block RCB may include multiple rewritable lookup tables (LUT) and flip-flops, which are not illustrated, and logic can be reconfigured by rewriting the lookup tables. The reconfiguration block RCB may also include an interconnect INTC in which multiple interconnect registers ICREG that combine a flip-flop FF and a multiplexer MUX may be disposed at predetermined intervals. The flip-flop FF is an example of a latch circuit. Hereinafter, the lookup table is also referred to as the LUT.

The interconnect registers ICREG may be arranged in the horizontal direction X of FIG. 1 and may be connected with one another through the interconnect. The multiplexer MUX of the interconnect register ICREG may select and output either an output from an interconnect register ICREG at a previous stage or an output of its flip-flop FF. This can selectively insert a predetermined number of flip-flops FF at any position to the interconnect INTC.

By using the interconnect INTC, timings of signals transferred between circuit blocks can be optimally set in accordance with, for example, the size of the multiple circuit blocks implemented along the horizontal direction X of the reconfiguration block RCB and the processing time in the circuit block. As a result, the performance of data processing by using multiple circuit blocks and the like can be improved in comparison with the performance obtained when the interconnect INTC is not used.

The hard functional block HFB may implement arithmetic units OP such as multiple fused multiply-add (FMA) units as non-reconfigurable hardware. The arithmetic unit OP is an example of a first arithmetic unit. Hereinafter, the arithmetic unit OP implemented in the hard functional block HFB is also referred to as the hard arithmetic unit OP. The function of the arithmetic unit OP implemented in the hard functional block HFB can be implemented by logic circuits programmed in the reconfiguration block RCB, although the implementation size is large.

FIG. 1 illustrates an example in which the memory block MEMB, the reconfiguration block RCB, and the hard functional block HFB are repeatedly arranged, but the number and the order of the memory blocks MEMB, the reconfiguration blocks RCB, and the hard functional blocks HFB are not limited to the example illustrated in FIG. 1. For example, the memory block MEMB may be provided for two sets of the reconfiguration block RCB and the hard functional block HFB.

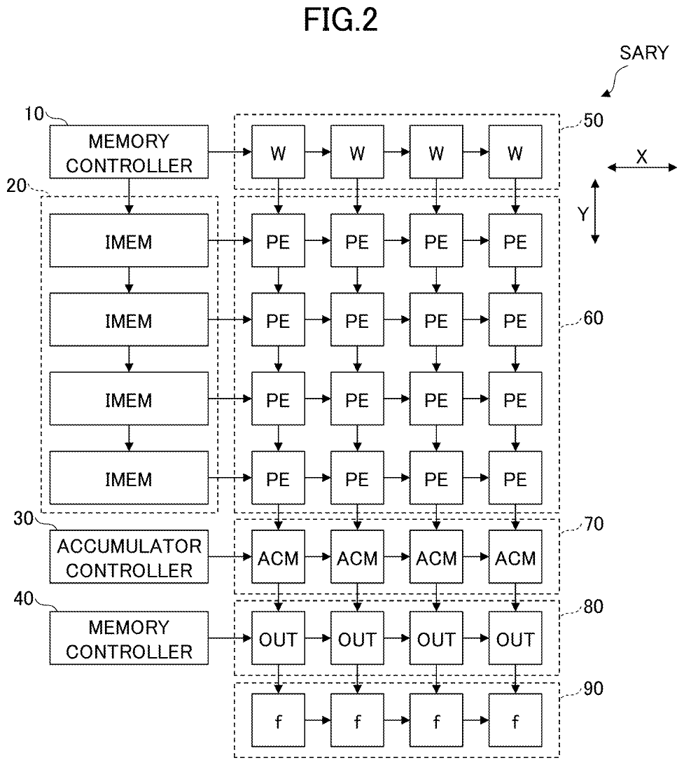

FIG. 2 is a block diagram illustrating an example of a systolic array SARY implemented in the semiconductor device 100 of FIG. 1. The systolic array SARY may include a memory controller 10, an internal memory unit 20, an accumulator controller 30, a memory controller 40, a weight memory unit 50, a processing element unit 60, an accumulator unit 70, an output memory unit 80, and a function unit 90. The memory controllers 10 and 40 and the accumulator controller 30 are examples of a controller.

The systolic array SARY may perform deep learning by using any bit number of floating-point data including, for example, 32-bit floating-point data or 64-bit floating-point data, but may perform deep learning by using fixed-point data.

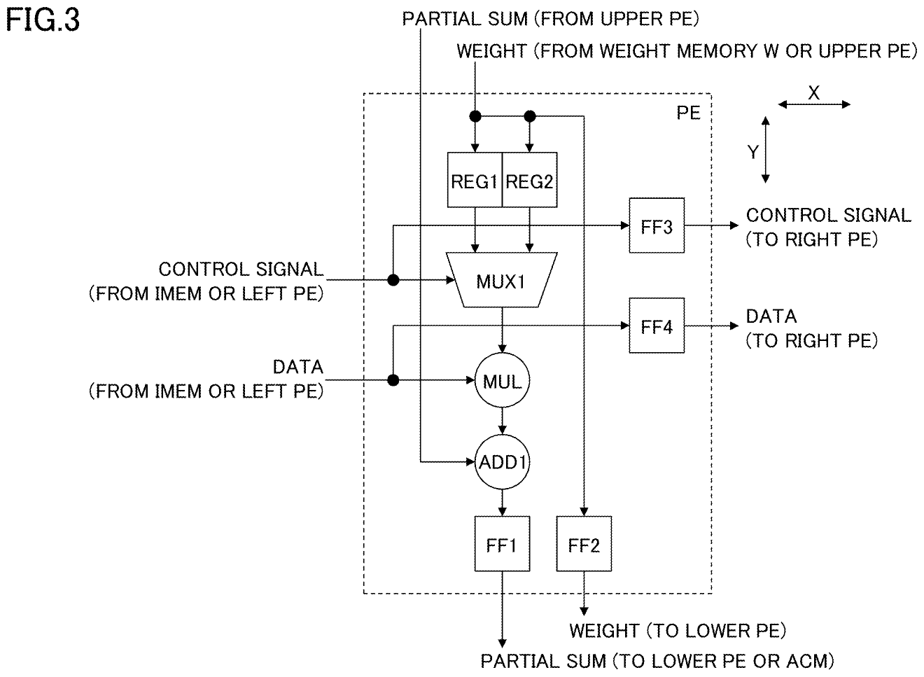

The processing element unit 60 may include multiple processing elements PE arranged in a matrix. The processing element PE is an example of a processing unit. An example of the processing element PE is illustrated in FIG. 3. The weight memory unit 50 may include multiple weight memories arrayed along the horizontal direction X that respectively retain weights corresponding to columns of the processing elements PE arranged in the vertical direction Y in FIG. 2. For example, a weight is supplied from the outside of the systolic array SARY and is used for deep learning of a neural network (e.g., convolution). Hereinafter, the weight memory retaining the weight is referred to as the weight memory W.

For example, each weight memory W is implemented in the memory block MEMB adjacent to the reconfiguration block RCB (FIG. 1) in which logic circuits of processing elements PE in a first row are implemented. The processing elements PE in the first row may be processing elements PE into which the weights are input. This can minimize the length of a transmission path of the weight from each weight memory W to a corresponding processing element PE, and minimize the transfer time of the weight.

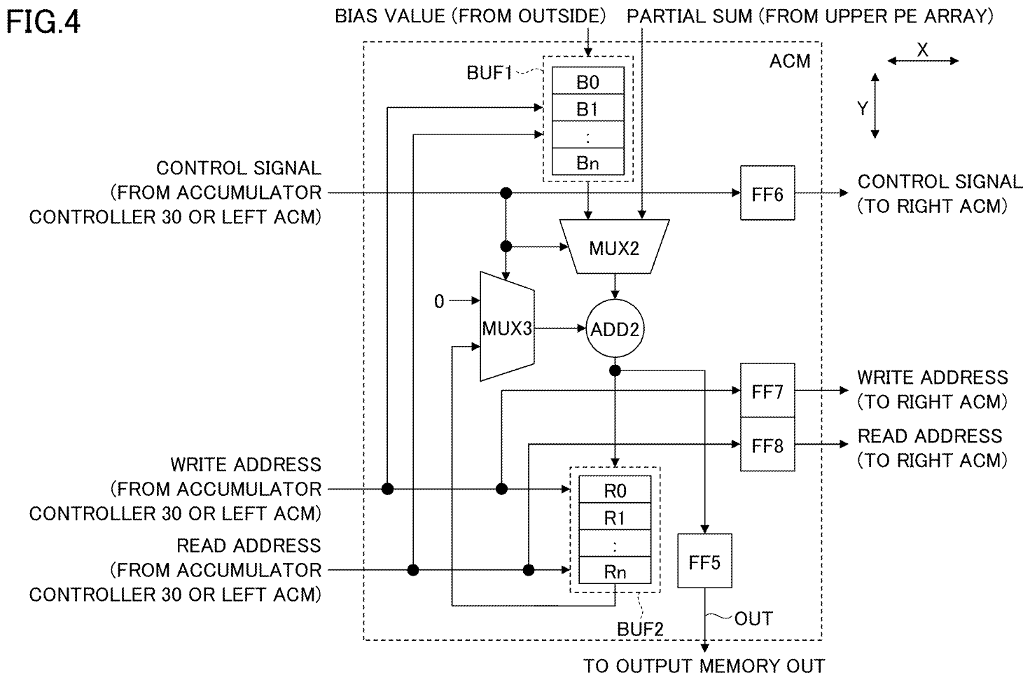

The accumulator unit 70 may include multiple accumulators ACM arrayed along the horizontal direction X that are corresponding to columns of the processing elements PE arranged in the vertical direction Y in FIG. 2. An example of the accumulator ACM is illustrated in FIG. 4. For example, the accumulator ACM may be implemented in a reconfiguration block RCB in which processing elements PE in a last row may be implemented, or in a reconfiguration block RCB subsequent to the reconfiguration block RCB in which the processing elements PE in the last row may be implemented.

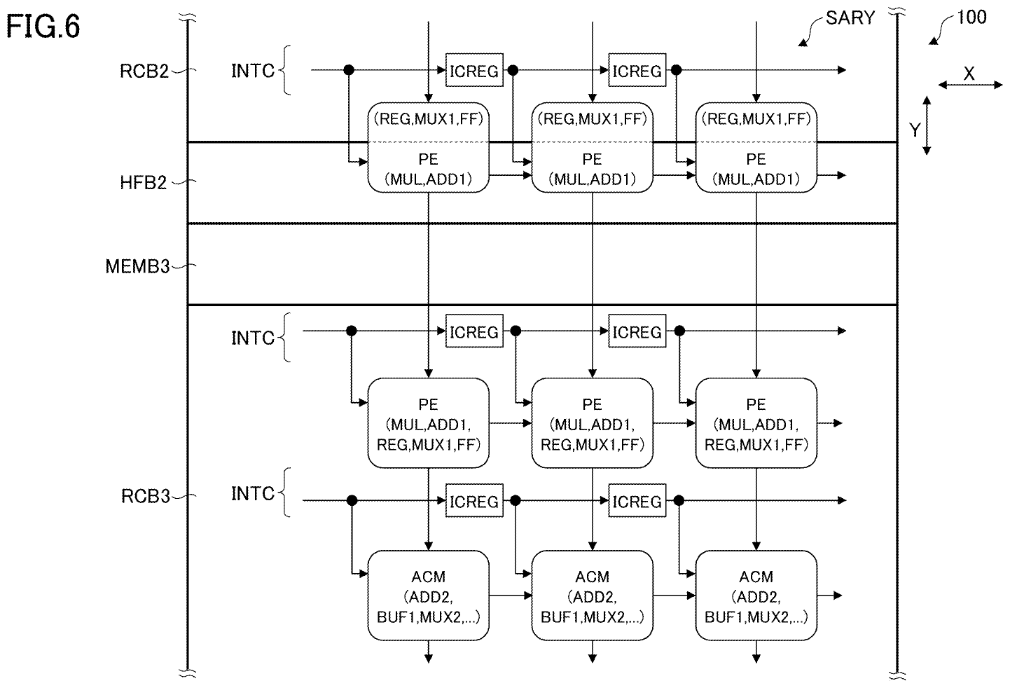

As will be described with reference to FIG. 6, an adder ADD2 (FIG. 4) included in the accumulator ACM may be implemented in a hard functional block HFB adjacent to a reconfiguration block RCB in which the logic circuit of the accumulator ACM is implemented.

The output memory unit 80 may include multiple output memories OUT arrayed along the horizontal direction X that respectively retain output data output from the accumulators ACM. For example, each output memory OUT is implemented in a memory block MEMB adjacent to a reconfiguration block RCB in which the logic circuit of the accumulator ACM is implemented. This can minimize the length of a transmission path of the output data from each accumulator ACM to a corresponding output memory OUT, and minimize the transmission time of the output data.

The function unit 90 may include multiple arithmetic parts f disposed along the horizontal direction X that respectively calculate the output data output from the output memories OUT by using a predetermined activation function. For example, the function unit 90 is implemented in a reconfiguration block RCB in which the logic circuit of the accumulator ACM is implemented, or in a reconfiguration block RCB subsequent to the reconfiguration block RCB in which the logic circuit of the accumulator ACM is implemented. If the arithmetic part f includes an arithmetic unit such as a multiplier, the arithmetic part f may be implemented in the hard functional block HFB adjacent to the reconfiguration block RCB in which the logic circuit of the function unit 90 is implemented.

The memory controller 10 may control reading and writing of the internal memory unit 20 based on a control signal to store data and a command in each internal memory IMEM and may output the data and the command from each internal memory IMEM to the processing element unit 60. The memory controller 10 may control reading and writing of the weight memory unit 50 based on a control signal to store the weight in the weight memory unit 50 and may output the weight from the weight memory unit 50 to the processing element unit 60.

The control signal supplied from the memory controller 10 to storage areas of the weight may be transferred sequentially from a storage area of the weight close to the memory controller 10. For example, the memory controller 10 is implemented in a reconfiguration block RCB adjacent to a memory block MEMB in which the weight memory W and an internal memory IMEM connected to the processing element PE in the upper left side of FIG. 2 are implemented. This can minimize the length of a control signal line or a data signal line connecting the memory controller 10, the internal memory IMEM, and the weight memory W, and can prevent an increase of the access time of the internal memory IMEM and the weight memory W. The processing element PE in the upper left side of FIG. 2 may be a starting point of an operation of the systolic array SARY.

The internal memory unit 20 may include internal memories IMEM corresponding to rows of the processing elements PE arrayed in the horizontal direction X in FIG. 2 in the processing element unit 60. Each internal memory IMEM may retain a command and data supplied from the outside of the systolic array SARY and may sequentially supply the retained command and data to a corresponding processing element PE based on a control signal from the memory controller 10. Here, a command is one of data.

For example, each internal memory IMEM may be implemented in a memory block MEMB adjacent to a reconfiguration block RCB in which a corresponding processing element PE is implemented. This can minimize the length of a transmission path of the command and data from each internal memory IMEM to the processing element PE and minimize the transmission time of the command and data. The control signals supplied from the memory controller 10 to the internal memories IMEM may be sequentially transferred from an internal memory IMEM close to the memory controller 10 to an internal memory IMEM far from the memory controller 10.

The accumulator controller 30 may output a command (i.e., a control signal) to each accumulator ACM of the accumulator unit 70 and may control the operation of each accumulator ACM. The command supplied to an accumulator ACM on the left side of FIG. 2 may be sequentially transferred to an accumulator ACM on the right side of FIG. 2. For example, the accumulator controller 30 is implemented in a reconfiguration block RCB in which the logic circuit of the accumulator ACM is implemented. This can minimize the length of a control signal line connecting the accumulator controller 30 to each accumulator ACM, and prevent delays in control of each accumulator ACM.

The memory controller 40 may control reading and writing of the output memory unit 80 based on a control signal to cause the output memory unit 80 to store data output from the accumulator ACM and output the output data from the output memory unit 80 to the function unit 90. For example, the memory controller 40 is implemented in a reconfiguration block RCB adjacent to a memory block MEMB in which the output memory OUT is implemented. This can minimize the length of a control signal line connecting the memory controller 40 to each output memory OUT, and prevent an increase of the access time of each output memory OUT.

In a row of the processing elements PE arranged in the horizontal direction X of FIG. 2, a processing element PE on the left side may transfer the data and the control signal supplied from the internal memory unit 20 to an adjacent processing element PE on the right side. Similarly, in a column of the processing elements PE arranged in the vertical direction Y of FIG. 2, a processing element PE on the upper side may transfer the weight supplied from the weight memory unit 50 and the data obtained by an arithmetic operation to an adjacent processing element PE on the lower side.

In the systolic array SARY illustrated in FIG. 2, the processing element unit 60 may sequentially transfer the weight from the weight memory W and the data from the internal memory IMEM, from a processing element PE on the upper left to a processing element PE on the lower right to perform a convolution operation and calculate a partial sum. The accumulator ACM of the accumulator unit 70 may accumulate the partial sums output from the processing elements PE located on the upper side of FIG. 2, may add a bias (which is not illustrated), and may store results in the output memory unit 80 as the output data.

The output memory unit 80 may output the output data to the function unit 90 based on the control performed by the memory controller 40. The function unit 90 may perform arithmetic operations on the output data by using the activation function to generate output data. For example, the activation function may be a sigmoid function or a softmax function.

By using the systolic array SARY implemented in the semiconductor device 100, deep learning of a neural network including multiple layers (e.g., training including a convolution operation) is performed, for example. Here, the systolic array SARY may be used for inference as well as training of a neural network.

FIG. 3 is a block diagram illustrating an example of the processing element PE of FIG. 2. The processing element PE may include a predetermined number of registers REG (in this example, REG1 and REG2), a multiplexer MUX1, a multiplier MUL, an adder ADD1, and multiple flip-flops FF (FF1, FF2, FF3, and FF4). The registers REG1 and REG2, the multiplexer MUX1, and the flip-flops FF1, FF2, FF3, and FF4 are examples of a first logic circuit. The multiplier MUL and the adder ADD1 are examples of a second arithmetic unit.

The registers REG1 and REG2 may retain the weight received from the weight memory W or from an upper processing element PE. For example, the registers REG1 and REG2 alternately may retain the weight and may alternately output the retained weight. The operation of the registers REG1 and REG2 may be controlled by control signals output from the internal memory IMEM. For example, the number of registers REG disposed in the processing element PE may be determined depending on the transfer rate of the weight and the processing rate of the processing element PE, and may be one, three, or more.

The multiplexer MUX1 may be controlled by a control signal output from the internal memory IMEM or a left processing element PE, may select one of the weights retained by the registers REG1 and REG2, and then may output the selected weight to the multiplier MUL. The multiplier MUL may multiply data output from the internal memory IMEM or a left processing element PE by the weight received from the multiplexer MUX1 and may output a multiplication result to the adder ADD1.

The adder ADD1 may add the multiplication result of the multiplier MUL to the partial sum received from an upper processing element PE and may output an addition result to the flip-flop FF1. As described above, each processing element PE may sequentially multiply the data by the weight, and may sequentially add the multiplication result to a multiplication result obtained by another processing element PE to generates the partial sum. In the entire systolic array SARY illustrated in FIG. 2, for example, a convolution operation of deep learning is performed.

The flip-flop FF1 may output the addition result to a lower processing element PE or the accumulator ACM. The flip-flop FF2 may output the weight received from the weight memory W or an upper processing element PE to a lower processing element PE.

The flip-flop FF3 may output a control signal from the internal memory IMEM or from a left processing element PE to a right processing element PE. The flip-flop FF4 may output data output from the internal memory IMEM or from a left processing element PE to a right processing element PE. For example, the flip-flops FF3 and FF4 are implemented using the flip-flops FF of the interconnect registers ICREG disposed in the reconfiguration block RCB.

FIG. 4 is a block diagram illustrating an example of the accumulator ACM of FIG. 2. The accumulator ACM may include buffer memories BUF1 and BUF2, multiplexers MUX2 and MUX3, an adder ADD2, and multiple flip-flops FF (FF5, FF6, FF7, and FF8). The multiplexers MUX2 and MUX3 and the flip-flops FF5 to FF8 are examples of a second logic circuit. The adder ADD2 is an example of a third arithmetic unit.

The buffer memory BUF1 may include n+1 storage areas B (B0, B1, . . . , Bn) that retain bias values supplied from the outside of the systolic array SARY (where n is a positive number greater than or equal to 1). The buffer memory BUF1 may store a received bias value in a storage area B indicated by the write address, may read a bias value from a storage area B indicated by the read address, and may output the read bias value to the multiplexer MUX2.

The write and read addresses may be transferred from the accumulator controller 30 or a left accumulator ACM. The write address and the read address supplied to the buffer memory BUF1 may be independent of the write address and the read address supplied to the buffer memory BUF2.

The multiplexer MUX2 may select the bias value from the buffer memory BUF1 or the partial sum from an upper processing element PE in accordance with the control signal, and may output the selected value to the adder ADD2. The control signal may be transferred from the accumulator controller 30 or from a left accumulator ACM.

The multiplexer MUX3 may select “0” or data output from the buffer memory BUF2 in accordance with the control signal and may output the selected value to the adder ADD2. For example, in a cycle in which a partial sum is firstly received from a processing element PE of a previous stage, the multiplexer MUX3 selects “0” to prevent invalid data retained in the buffer memory BUF2 from being added by the adder ADD2. The control signal supplied to the multiplexer MUX2 may be independent of the control signal supplied to the multiplexer MUX3.

The adder ADD2 may add the output of the multiplexer MUX2 to the output of the multiplexer MUX3, and may output the addition result to the buffer memory BUF2 and the flip-flop FF5. The buffer memory BUF2 may include n+1 storage areas R (R0, R1, . . . , Rn) that retain the addition results obtained by the adder ADD2. The buffer memory BUF2 may store the received addition result in a storage area R indicated by the write address, may read the addition result from a storage area R indicated by the read address, and may output the read addition result to the multiplexer MUX3.

The flip-flop FF6 may output a control signal output from the accumulator controller 30 or from a left accumulator ACM to a right accumulator ACM. The flip-flop FF7 may output a write address output from the accumulator controller 30 or from a left accumulator ACM to a right accumulator ACM. The flip-flop FF8 may output a read address output from the accumulator controller 30 or a left accumulator ACM to a right accumulator ACM.

For example, the flip-flops FF6, FF7, and FF8 are implemented using the flip-flops FF of the interconnect registers ICREG disposed in the reconfiguration block RCB. The accumulator ACM may repeat an operation of sequentially adding the partial sum from the processing element PE of the previous stage with the adder ADD2, and may add the bias value to generate the output data, and may output the generated output data to the output memory OUT.

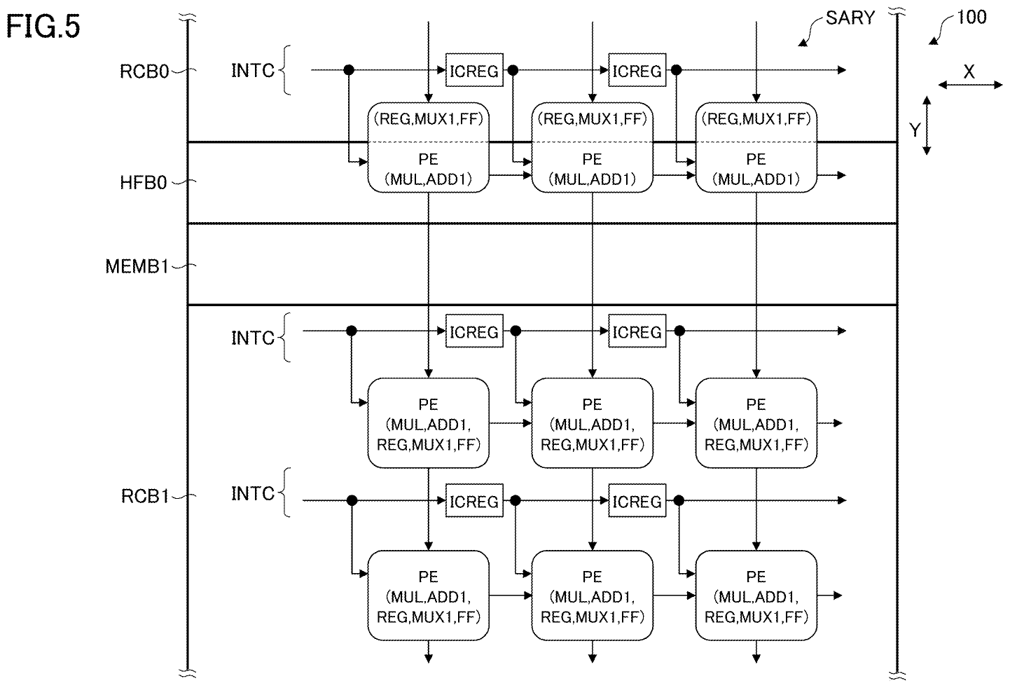

FIG. 5 is an explanatory diagram illustrating an example of the systolic array SARY implemented on the semiconductor device 100 of FIG. 1. FIG. 5 also illustrates an outline of a layout (i.e., mapping) of the processing elements PE on the semiconductor device 100, which may be determined before implementing the processing elements PE on the semiconductor device 100.

In the present specification, the “layout” does not indicate a process of programming a circuit in the semiconductor device 100, but indicates a process of generating mapping data (i.e., layout data) indicating positions of implementing circuits on the semiconductor device 100 using an FPGA tool, which will be described below. Hereinafter, a process of generating mapping data by using an FPGA tool to determine positions of implementing circuits on the semiconductor device 100 is referred to as mapping.

FIG. 5 illustrates a portion having three rows and three columns of processing elements PE in the systolic array SARY illustrated in FIG. 2. In FIG. 5, the memory controller 10, the internal memory unit 20, the accumulator controller 30, the memory controller 40, the weight memory unit 50, the accumulator unit 70, the output memory unit 80, and the function unit 90 that are illustrated in FIG. 2 are omitted.

For example, the memory controller 10, the accumulator controller 30, the memory controller 40, and the function unit 90 are implemented in the reconfiguration block RCB. The arithmetic part f of the function unit 90 may be implemented in the hard functional block HFB if the hard arithmetic unit OP in the hard functional block HFB is available. The internal memory IMEM of the internal memory unit 20, the weight memory W of the weight memory unit 50, and the output memory OUT of the output memory unit 80 may be implemented in the memory block MEMB.

The processing elements PE illustrated on the upper side of FIG. 5 may be implemented by being distributed in the reconfiguration block RCB0 and the hard functional block HFB0 that are disposed adjacent to each other. That is, the multiplier MUL and the adder ADD1 may be implemented in the hard functional block HFB0, and elements other than the multiplier MUL and the adder ADD1 (REG1, REG2, MUX1, and FF1 to FF4) may be implemented in the reconfiguration block RCB0. The circuits in the reconfiguration block RCB may be implemented using the LUT provided in the reconfiguration block RCB.

This can minimize the length of interconnects in the processing element PE, if the processing element PE is implemented on the semiconductor device 100 using the hard functional block HFB having only the hard arithmetic unit OP. For example, in FIG. 3, the length of an interconnect from the multiplexer MUX1 to the multiplier MUL and the length of an interconnect from the adder ADD1 to the flip-flop FF1 can be minimized. Therefore, the processing performance of the processing element PE can be prevented from being degraded due to an increase of the length of the interconnect.

For example, the memory controller 10 may be implemented in a reconfiguration block RCB that implements the processing elements PE in a first row (FIG. 2). The accumulator controller 30 and the memory controller 10 may be implemented in a reconfiguration block RCB that implements a last row of the processing elements PE.

In this case, by implementing the multiplier MUL and the adder ADD1 of the processing element PE in the hard functional block HFB, logic other than the processing element PE can be implemented in the reconfiguration block RCB. Hereinafter, a row of processing elements PE that are arranged in the horizontal direction X is also referred to as a processing row.

Here, in the hard functional block HFB, multipliers MUL and adders ADD1 of two or more rows of the processing elements PE may be implemented. If multipliers MUL and adders ADD1 of two rows of the processing elements PE are implemented in the hard functional block HFB, the logic circuits of the processing element PE on a first row side may be implemented in a reconfiguration block RCB on the first row side.

The logic circuits of the processing element PE on a last row side may be implemented in a reconfiguration block RCB on the last row side. Thereby, a physical array of the matrix configuration of the processing elements PE in the systolic array SARY can be achieved on the semiconductor device 100 without change. As a result, the signal line length between the processing elements PE can be minimized, thereby preventing degradation of the performance of the systolic array SARY.

In the example illustrated in FIG. 5, in the reconfiguration block RCB1, two or more processing rows of the processing elements PE are implemented. The processing element PE implemented in the reconfiguration block RCB1 includes all elements (i.e., the multiplier MUL, the adder ADD1, and the logic circuits) in the reconfiguration block RCB1.

In the present embodiment, arithmetic units in the processing element PE can be implemented in either the reconfiguration block RCB or the hard functional block HFB, depending on a position of the processing element PE in the systolic array SARY. That is, it can be selected whether all elements of the processing element PE can be implemented in the reconfiguration block RCB or only the logic circuits can be implemented in the reconfiguration block RCB.

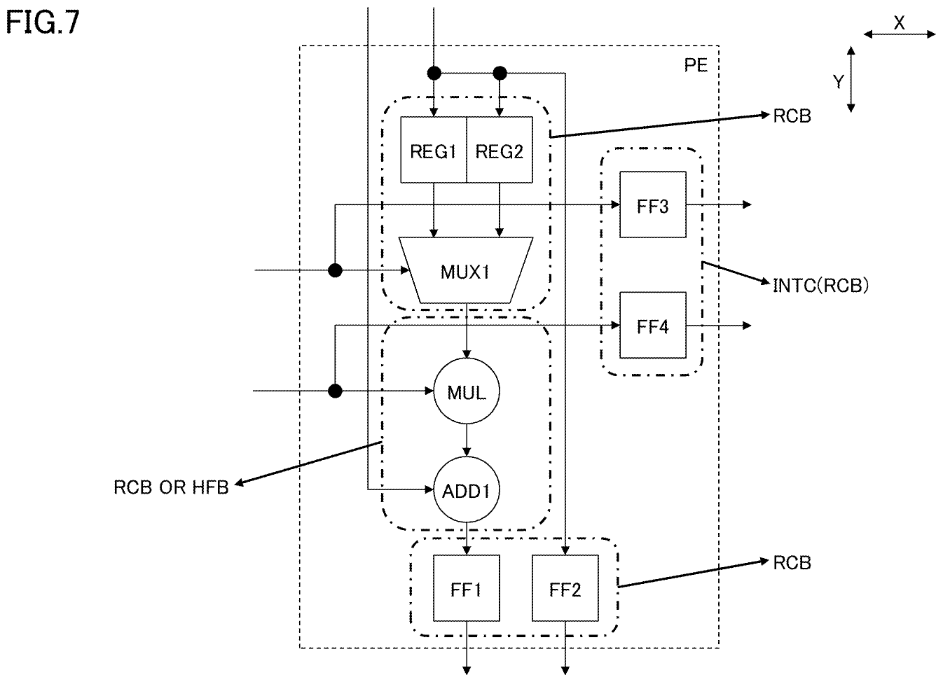

As a result, the use efficiency of the reconfiguration block RCB can be improved and the implementation efficiency of the systolic array SARY on the semiconductor device 100 can be improved. Whether each element of the processing element PE may be implemented in the reconfiguration block RCB or the hard functional block HFB will be described in FIG. 7. If an arithmetic unit having the same function as the hard arithmetic unit OP implemented in the hard functional block HFB is implemented in the reconfiguration block RCB by using the LUT, the implementation area of the arithmetic unit in the reconfiguration block RCB is larger than the implementation area of the hard arithmetic unit OP.

In the interconnect INTC, the interconnect register ICREG may be selected from the multiple interconnect registers ICREG to use the flip-flop FF in accordance with the circuit size and the processing speed of the processing element PE. This can transfer a control signal and data to each processing element PE in accordance with the processing speed of each processing element PE, thereby improving the performance of the systolic array SARY. Here, the interconnect INTC may be disposed along the horizontal direction X in a region separate from the reconfiguration block RCB.

FIG. 6 is an explanatory diagram illustrating another example of the systolic array SARY implemented on the semiconductor device 100 of FIG. 1. FIG. 6 also illustrates an outline of mapping of the processing elements PE and the accumulators ACM on the semiconductor device 100. For elements substantially the same as the elements in FIG. 5, the detailed description is omitted. The mapping of the processing elements PE on the semiconductor device 100 is similar to the mapping of FIG. 5. Similarly with FIG. 5, the description of elements other than the processing element PE and the accumulator ACM is omitted.

In FIG. 6, the accumulator ACM connected to a last row of the processing elements PE arranged in the horizontal direction X may be mapped to the reconfiguration block RCB3 to which the last row of the processing elements PE is mapped. That is, each accumulator ACM may be implemented using the LUT of the reconfiguration block RCB with including the adder ADD2.

Here, a case may be assumed in which the number of LUTs of the reconfiguration blocks RCB3 in the vertical direction Y is insufficient, and the adder ADD2 of the accumulator ACM cannot be mapped to the reconfiguration block RCB3. In this case, the adder ADD2 may be mapped to an arithmetic unit OP of a hard functional block HFB3 (which is not illustrated) provided on a later stage side from the reconfiguration block RCB3 (i.e., on a lower side of FIG. 6).

Alternatively, a case may be assumed in which the number of LUTs of the reconfiguration blocks RCB3 in the vertical direction Y is insufficient, and the accumulator ACM cannot be mapped to reconfiguration block RCB3. In this case, the accumulator ACM may be mapped to the next reconfiguration block RCB4, which is not illustrated, provided on the latter stage side from the reconfiguration block RCB3. Alternatively, the adder ADD2 of the accumulator ACM may be mapped to the hard functional block HFB3, which is not illustrated, provided on the latter stage side from the reconfiguration block RCB3, and the logic circuits of the accumulator ACM may be mapped to the next reconfiguration block RCB4.

As described, in accordance with the LUT usage amount of the reconfiguration block RCB, the reconfiguration block RCB to which the processing element PE and the accumulator ACM are mapped can be changed. Additionally, in accordance with the LUT usage amount of the reconfiguration block RCB, the adder ADD2 of the accumulator ACM can also be mapped to either the reconfiguration block RCB or the hard functional block HFB.

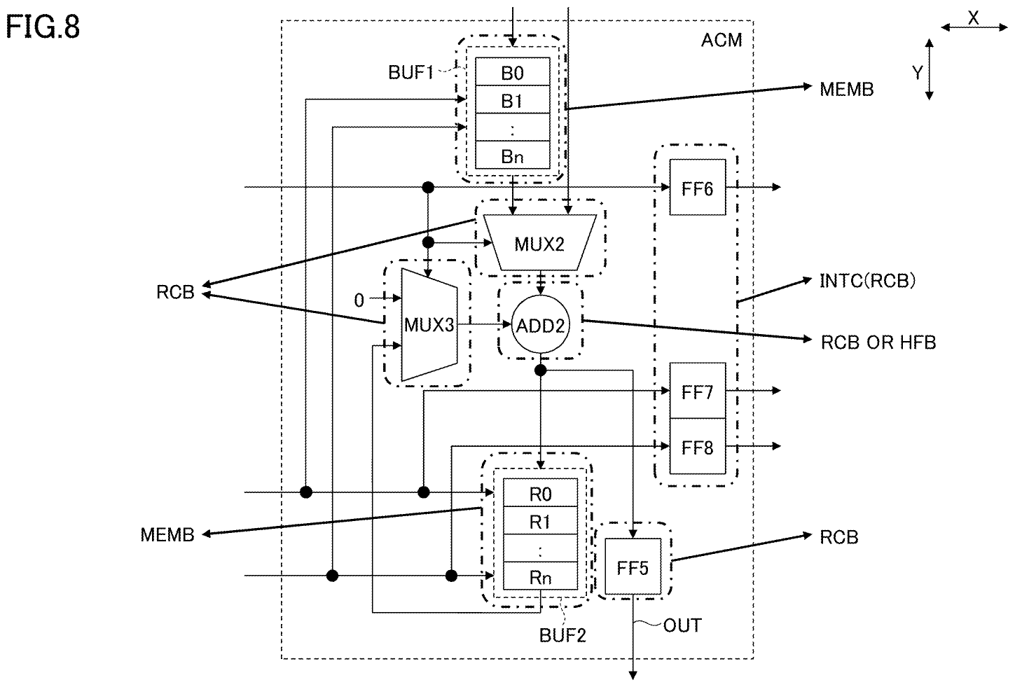

This can map the processing element PE and the accumulator ACM to locations where the LUTs can be used without waste, and minimize the length of the signal line connecting the processing element PE and the accumulator ACM. As a result, transfer delays of the data between processing elements PE and between the processing element PE and the accumulator ACM can be minimized, for example, and the processing efficiency (the processing speed and bandwidth) of the systolic array SARY can be improved. Whether respective elements of the accumulator ACM are implemented in the reconfiguration block RCB, the hard functional block HFB, or the memory block MEMB will be described with reference to FIG. 8.

FIG. 7 is an explanatory diagram illustrating a block to which each element of the processing element of FIG. 2 is implemented (or mapped). The multiplier MUL and the adder ADD1 my be implemented in either the reconfiguration block RCB or the hard functional block HFB. The registers REG1 and REG2, the multiplexer MUX1, and the flip-flops FF1 and FF2 that transmit a signal in the vertical direction Y of FIG. 7 may be implemented in the reconfiguration block RCB. The flip-flops FF3 and FF4 that transmit a signal to the horizontal direction X of FIG. 7 may be implemented using the flip-flops FF of the interconnect registers ICREG disposed in the reconfiguration block RCB.

As illustrated in FIG. 7, the processing element PE can be made by implementing all elements in only the reconfiguration block RCB (using the LUTs). Alternatively, the processing element PE can be made by implementing the multiplier MUL and the adder ADD1 in the hard functional block HFB and implementing the logic circuits other than the multiplier MUL and the adder ADD1 in the reconfiguration block RCB.

FIG. 8 is an explanatory diagram illustrating a block to which each element of the accumulator of FIG. 2 is implemented (or mapped). The adder ADD2 may be implemented in the reconfiguration block RCB or the hard functional block HFB. The buffer memories BUF1 and BUF2 may be implemented in the memory block MEMB. The multiplexers MUX2 and MUX3 and the flip-flop FF5 that transfers a signal in the vertical direction Y of FIG. 8 may be implemented in the reconfiguration block RCB. The flip-flops FF6, FF7, and FF8 that transfer signals in the horizontal direction X of FIG. 8 may be implemented using the flip-flops FF of the interconnect registers ICREG disposed in the reconfiguration block RCB.

As illustrated in FIG. 8, the accumulator ACM can be made by implementing all elements in the reconfiguration block RCB (using the LUTs) and the memory block MEMB. Alternatively, the accumulator ACM can be made by implementing the adder ADD2 in the hard functional block HFB and implementing elements other than the adder ADD2 in the reconfiguration block RCB and the memory block MEMB.

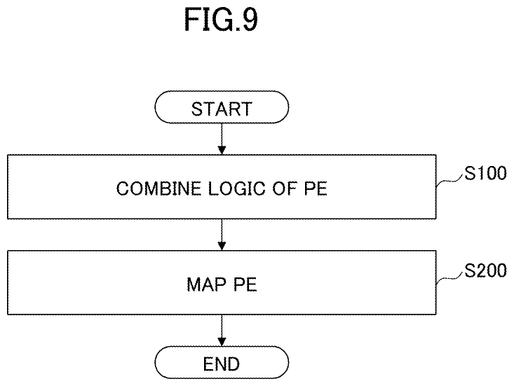

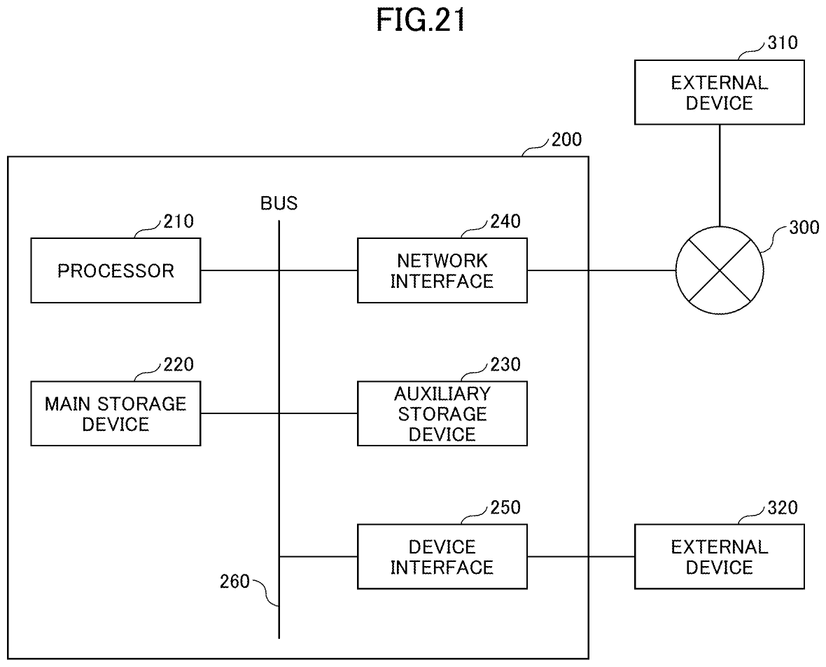

FIG. 9 is a flowchart for mapping the processing elements PE of the systolic array SARY of FIG. 2 to the semiconductor device 100 of FIG. 1. The processing flow illustrated in FIG. 9 may be achieved by executing a circuit layout program with an FPGA tool to arrange desired functional circuits on the semiconductor device 100 (FPGA). The flow illustrated in FIG. 9 may indicate an example of a circuit layout method achieved by executing a circuit layout program. In FIG. 9, the description of a process of mapping elements other than the processing element PE of the systolic array SARY is omitted. A hardware configuration of the FPGA tool will be described with reference to FIG. 21.

First, in step S100, the FPGA tool may disable the hard functional block HFB, may enable the reconfiguration block RCB and the LUTs, and may combine the logic of the processing element PE to include the multiplier MUL and the adder ADD1, which have been enabled to be mapped to the hard functional block HFB, in the processing element PE. Next, in step S200, the FPGA tool may map the processing element PE to which the PE synthesis has been performed to the reconfiguration block RCB.

This may enable the FPGA tool to obtain information about the number of LUTs used to map one processing element PE to the reconfiguration block RCB. The FPGA tool may store the number of LUTs in the horizontal direction X and the number of LUTs in the vertical direction Y that are used to implement the processing element PE in the reconfiguration block RCB, for example, in a memory in the FPGA tool for mapping the processing element PE.

Here, the numbers of LUTs used in the processing element PE in the horizontal direction X and in the vertical direction Y can be changed, and the number of LUTs in the horizontal direction X increases as the number of LUTs in the vertical direction Y decreases. Even if the numbers of LUTs in the horizontal direction X and in the vertical direction Y are changed, the total number of LUTs used in the processing element PE may not be changed.

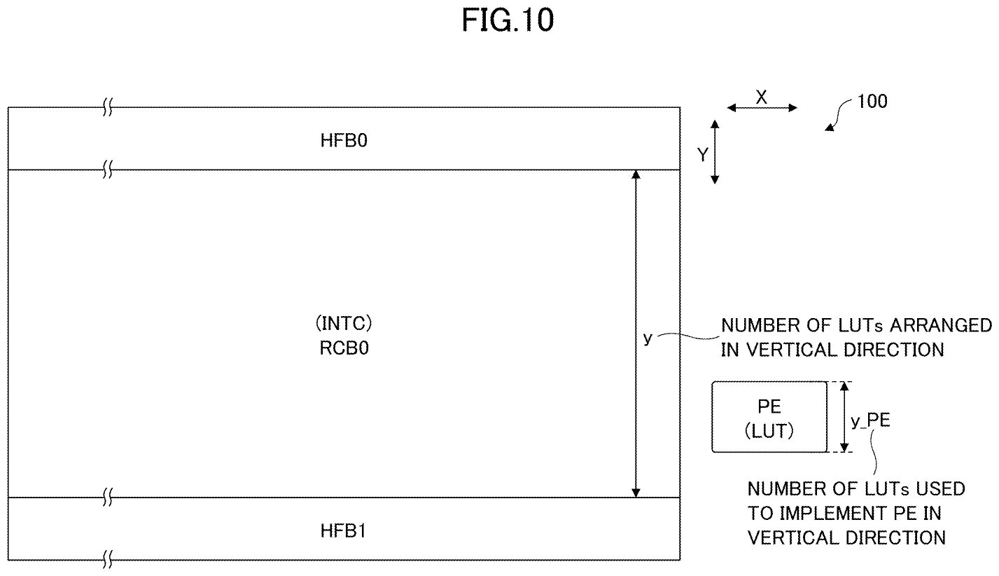

FIG. 10 is an explanatory diagram illustrating a relation between the number of LUTs in the reconfiguration block RCB of FIG. 1 and the number of LUTs used in the processing element PE implemented in the reconfiguration block RCB. As illustrated in FIG. 6, each circuit element of the processing element PE may be implemented using the LUTs of the reconfiguration block RCB. FIG. 10 illustrates a simplified model in which the memory block MEMB is removed from the semiconductor device 100 of FIG. 1. The use of the simplified model reduces the amount of resources used by the FPGA tool to determine the relationship between the numbers of LUTs.

The number of LUTs of the reconfiguration blocks RCB arranged in the vertical direction Y may be represented by a LUT number y, and the number of LUTs of the processing element PE in the vertical direction Y when the processing element PE may be implemented in the reconfiguration block RCB is represented by a LUT number y_PE. The FPGA tool may determine the number of the processing elements PE that can be arranged in the vertical direction Y of the reconfiguration block RCB by, for example, calculating an integer value (a rounding down number) by dividing the LUT number y by the LUT number y_PE.

In FIG. 10, the number of LUTs of the reconfiguration block RCB arranged in the horizontal direction X and the number of LUTs of the processing element PE in the horizontal direction X when the processing element PE is implemented in the reconfiguration block RCB are omitted. This is because, as illustrated in FIG. 1, the reconfiguration block RCB may be longer in the horizontal direction X and shorter in the vertical direction Y, so that the implementation of the processing element PE is rarely limited by the number of LUTs arranged in the horizontal direction X. In other words, because the number of processing elements PE in the horizontal direction X included in the systolic array SARY may be equivalent to the number of processing elements PE in the vertical direction Y included in the systolic array SARY (FIG. 2), the number of processing elements PEs that can be implemented in the reconfiguration block RCB is often limited by the number of processing elements arranged in the vertical direction Y.

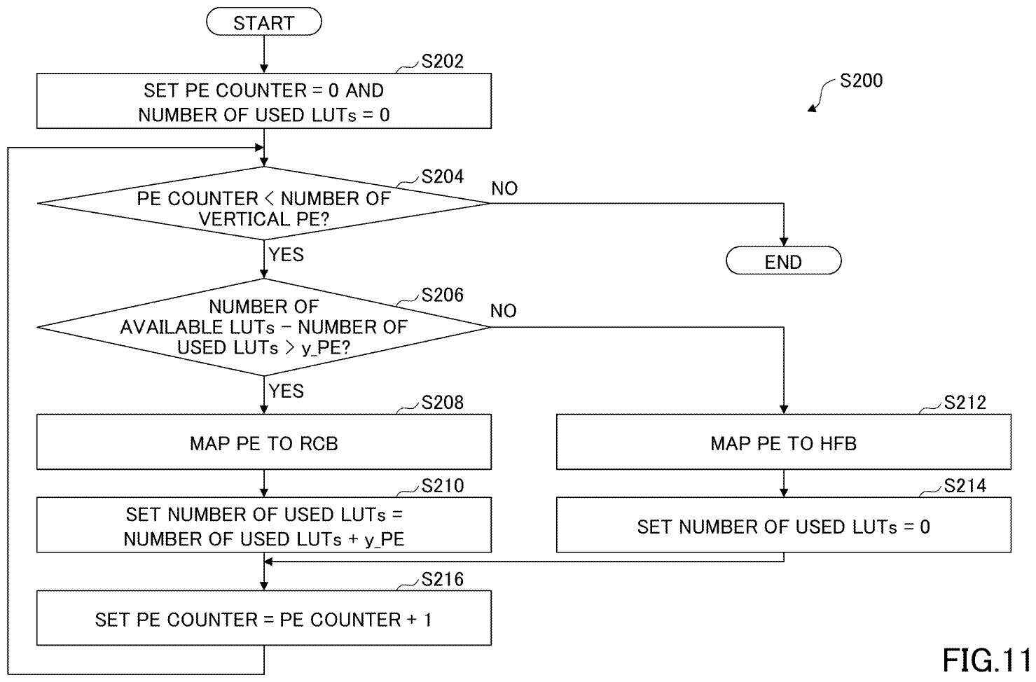

FIG. 11 is a flowchart illustrating an example of the processing of step S200 of FIG. 9. That is, FIG. 11 illustrates an example of a circuit layout method achieved by a processor, such as a CPU mounted to the FPGA tool, executing a circuit layout program.

First, in step S202, the processor may clear a PE counter and the number of used LUTs to “0”. The PE counter may indicate the number of processing elements PE arranged in the vertical direction Y that are mapped to the reconfiguration block RCB. The number of used LUTs is the number of LUTs arranged in the vertical direction Y that are used by the processing elements PE mapped to the reconfiguration block RCB. For example, the PE counter and the number of used LUTs are retained in general purpose registers implemented in the processor.

Next, in step S204, the processor may determine whether the value of the PE counter is less than the number of vertical PEs. The number of vertical PEs is the number of processing elements PE arranged in the vertical direction Y of the systolic array SARY, and, for example, “4” in FIG. 2. In step S204, the processor may determine whether all of the processing elements PE of the systolic array SARY have been mapped to the semiconductor device 100.

If the value of the PE counter is less than the number of vertical PEs, the processor may execute step S206 because there is a processing element PE that is not mapped to the semiconductor device 100 in the systolic array SARY. If the value of the PE counter is equal to the number of vertical PEs, the processor may terminate the process illustrated in FIG. 11 because all of the processing elements PE of the systolic array SARY have been mapped to the semiconductor device 100.

In step S206, the processor may determine whether a difference between the number of available LUTs and the number of used LUTs is greater than the LUT number y_PE that is the number of LUTs arranged in the vertical direction Y in the processing element PE. The number of available LUTs is the number of LUTs that can be used to map the processing element PE to the reconfiguration block RCB among LUTs arranged in the vertical direction in the reconfiguration block RCB.

For example, the number of available LUTs is a value obtained by subtracting the number of LUTs used by elements other than the processing element PE from the total number of LUTs of the reconfiguration block RCB in the vertical direction Y. Here, LUTs used by elements other than the processing element PE may be LUTs used by the memory controller 10, the accumulator controller 30, or the memory controller 40.

If the difference between the number of available LUTs and the number of used LUTs is greater than the LUT number y_PE, the processor may execute step 5208 because the processor can further map the processing element PE into a currently selected reconfiguration block RCB. If the difference between the number of vertical LUTs and the number of used LUTs is less than or equal to the LUT number y_PE, the processor may execute step S2I2 because the processor cannot map the processing element PE into the currently selected reconfiguration block RCB.

As described, in step S206, in the current reconfiguration block RCB selected to map the processing element PE, it may be determined whether the processing element PE can be mapped based on available LUTs arranged in the vertical direction Y. In other words, it may be determined whether the processing element PE can be mapped to the reconfiguration block RCB based on the size of the processing element PE in the vertical direction Y and the size of the reconfiguration block RCB in the vertical direction Y that can be used for the processing element PE. Thus, based on the comparison of the sizes in the vertical direction Y or the comparison of the numbers of LUTs in the vertical direction Y, it can be easily determined whether the processing element PE can be mapped to the reconfiguration block RCB.

In step S208, the processor may map the processing element PE to the currently selected reconfiguration block RCB by setting an indicator to arrange the processing element PE in the reconfiguration block RCB. That is, all the elements including the multiplier MUL and the adder ADD1 of the processing element PE may be mapped to the reconfiguration block RCB.

For example, mapping of the processing element PE is performed so that processing rows of the processing elements PE are arranged in the order from the top to the bottom of FIG. 1. Also, as illustrated in FIG. 2, if the systolic array SARY includes four processing elements PE in the horizontal direction X, in step S208, four processing elements PE arranged in the horizontal direction X are mapped.

Next, in step S210, the processor may update (or increase) the number of used LUTs by adding the LUT number y_PE to the number of used LUTs, and may proceed to step S216. In step S210, in the currently selected reconfiguration block RCB, the number of LUTs arranged in the vertical direction Y used for mapping the processing elements PE may be calculated as the used LUTs.

In step S212, the processor may select a hard functional block HFB adjacent to the currently selected reconfiguration block RCB because the mapping of the processing elements PE to one reconfiguration block RCB has been completed. Then, the processor may map the processing element PE to the hard functional block HFB by setting an indicator that causes the hard functional block HFB to implement the processing element PE.

This may cause the multiplier MUL and the adder ADD1 of the processing element PE to be mapped to the hard functional block HFB adjacent to the reconfiguration block RCB. For example, the hard functional block HFB adjacent to the reconfiguration block RCB is a hard functional block HFB located below the reconfiguration block RCB in FIG. 1. In this example, the processing elements PE corresponding to one row illustrated in FIG. 2 are mapped to the hard functional block HFB.

In the hard functional block HFB, the multipliers MUL and the adders ADD1 of the processing elements PE may be mapped, and the logic circuits of the processing elements PE are mapped to the reconfiguration block RCB. Here, the logic circuits are the resistors REG1, REG2, multiplexer MUX1, and flip-flops FF1, FF2, FF3, and FF4, which are illustrated in FIG. 6. For example, the logic circuits are mapped to the reconfiguration block RCB located above the hard functional block HFB. Thus, in step S206, it may be determined whether the logic circuits of the processing elements PE other than the multipliers MUL and the adders ADD1 can be mapped to the reconfiguration block RCB.

Additionally, if it is determined that the hard functional block HFB is used in step S206, there may be no sufficient space to map the logic circuits of the processing elements PE to the currently selected reconfiguration block RCB. In this case, the logic circuits of the processing elements PE are mapped to a reconfiguration block RCB to be selected next on a latter stage side.

Next, in step S214, the processor may clear the number of used LUTs to “0” and proceeds to step S216. This may set a next reconfiguration block RCB adjacent to the hard functional block HFB to which the processing elements in one row may be mapped to be a mapping target of the processing elements PE.

In step S216, the processor may increase the PE counter by “1” and may return to the process of step S204, because the processor has mapped the processing elements PE in one row to the reconfiguration block RCB or the reconfiguration block RCB and the hard functional block HFB. Then, the processor repeatedly may execute the process from step S204 to step S216 to map the processing elements PE constituting the systolic array SARY from the top to the bottom of the systolic array SARY to the top to the bottom of the semiconductor device 100.

In FIG. 11, a process of preferentially mapping the processing elements PE to the reconfiguration block RCB and mapping the processing elements PE to the hard functional block HFB when the reconfiguration block RCB has no available space may be repeated. This can improve the usage rate of the LUTs of each reconfiguration block RCB. Also, as illustrated in FIG. 5, the processing elements PE of the systolic array SARY can be implemented on the semiconductor device 100 in the order of the array.

Because the processing elements PE can be implemented in the order of the array, the processing elements PE can be connected with the minimized interconnect in comparison with a case in which the processing elements PE are not implemented in the order of the array, thereby minimizing the transfer delay of the signal between the processing elements PE. As a result, a decrease of the bandwidth of the systolic array SARY may be prevented.

Normally, because the hard functional block HFB may have limited resources, the mapping of the processing elements PE to the hard functional block HFB may be performed for arithmetic units in one processing row, so that the resources of the hard functional block HFB can be used effectively in another application. In other words, the processing elements PE may be preferentially mapped to the reconfiguration block RCB, so that the resources of the hard functional block HFB can be used effectively.

In the systolic array SARY illustrated in FIG. 2, the interconnect INTC can be used for a path of the control signal and the data sequentially transferred from the processing element PE on the left side to the processing element PE on the right side. Therefore, the control signal and the data can be sequentially transferred to the right processing element PE at the optimum timing in accordance with the processing time of the processing element PE. As a result, a decrease of the bandwidth of the systolic array SARY may be prevented.

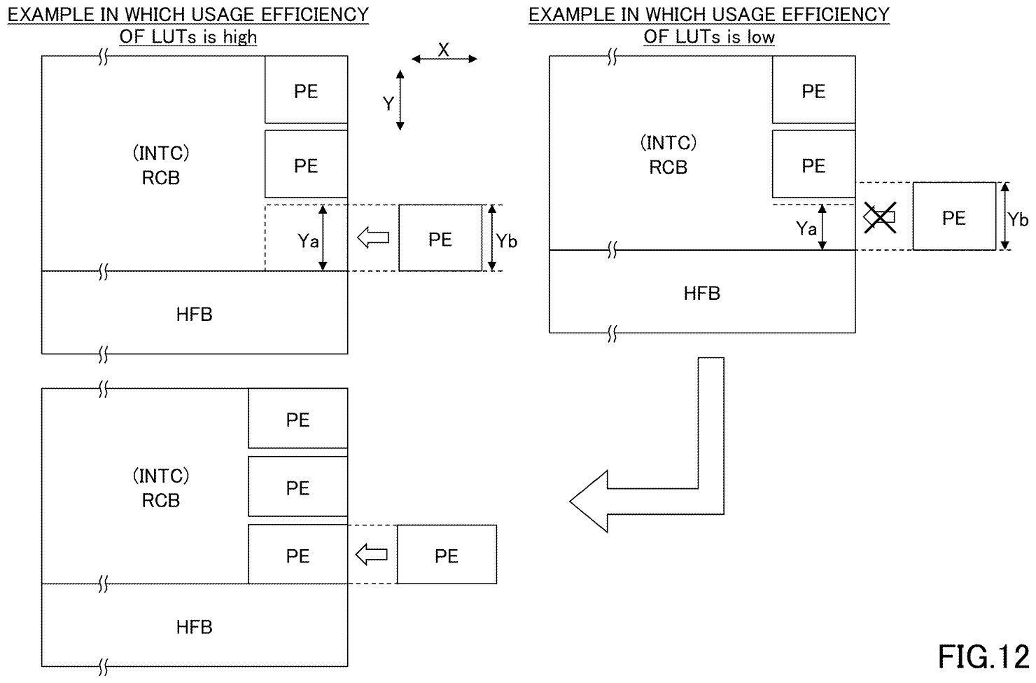

FIG. 12 is an explanatory diagram illustrating an example of mapping the processing elements PE to the reconfiguration block RCB. The process illustrated in FIG. 12 may be achieved by a processor, such as a CPU installed in the FPGA tool, executing a circuit layout program.

As in FIG. 10, a simplified model in which the memory block MEMB is removed from the semiconductor device 100 of FIG. 1 is illustrated in FIG. 12. In FIG. 12, only the processing elements PE arranged on the right end are illustrated, for the purpose of clear description, but in practice, multiple processing elements PE arranged in the horizontal direction X may be mapped to the reconfiguration block RCB.

The upper left part of FIG. 12 illustrates an example in which the number Ya of available LUTs arranged in the vertical direction Y that can be used for mapping the processing element PE in the reconfiguration block RCB is equal to or slightly greater than the number Yb of LUTs in the vertical direction Y used by the processing element PE. Here, the number Yb may be the LUT number y_PE.

In this case, the available LUTs of the reconfiguration block RCB that are arranged in the vertical direction Y can be used to map the processing element PE, thereby increasing the usage efficiency of the LUTs in the reconfiguration block RCB. Here, a space between the two processing elements PE in the vertical direction Y that are mapped to the reconfiguration block RCB is used, for example, for the interconnect INTC and the interconnect register ICREG (FIG. 1).

The upper right part of FIG. 12 illustrates an example in which the number Ya of available LUTs of the reconfiguration block RCB that are arranged in the vertical direction Y is less than the number Yb (i.e., y_PE) of LUTs used by the processing element PE in the vertical direction Y. Here, the number Ya of available LUTs may be a value obtained by “the number of available LUTs—the number of used LUTs” in step S206 of FIG. 11.

As the number Ya of available LUTs approaches the number Yb, the number of LUTs that cannot be used as the processing element PE increases, thereby reducing the usage efficiency of LUTs in the reconfiguration block RCB. Thus, if a ratio Ya/Yb is greater than or equal to a predetermined value, the processor of the FPGA tool may decrease the number of LUTs in the vertical direction Y and may increase the number of LUTs in the horizontal direction X, with respect to the LUTs that are used for mapping the processing elements PE.

This can increase the number of processing elements PE that can be mapped to the reconfiguration block RCB in the vertical direction Y, thereby preventing a decrease in the usage efficiency of LUTs in the reconfiguration block RCB. For example, if the ratio Ya/Yb is greater than or equal to 50% (but less than 100%), the processor may change the numbers of LUTs in the vertical direction and in the horizontal direction that are used for the processing element PE and may map the processing element PE to the reconfiguration block RCB again. The total number of LUTs used for mapping the processing element PE before changing the numbers of vertical LUTs and horizontal LUTs may be the same as the total number of LUTs used for mapping the processing element PE after changing the numbers of vertical LUTs and horizontal LUTs.

As described, even if there is not sufficient available space of the reconfiguration block RCB in the vertical direction Y, the mapping shape of the processing element PE can be changed to map the processing element PE to the reconfiguration block RCB if a predetermined condition is satisfied. This can improve the usage efficiency of the LUTs in the reconfiguration block RCB and improve the implementation efficiency of the systolic array SARY on the semiconductor device 100. Here, because a sufficient number of LUTs may be arranged in the horizontal direction X of the reconfiguration block RCB, no problem may occur due to an increase in the number of used LUTs in the horizontal direction X.

If the ratio Ya/Yb is less than 50%, the processor may determine whether only the logic circuits excluding the multiplier MUL and the adder ADD1 in the processing element PE can be mapped to the reconfiguration block RCB. If only the logic circuits of the processing element PE can be mapped to the reconfiguration block RCB, the processor may map the logic circuits to the reconfiguration block RCB and may map the multiplier MUL and the adder ADD1 to the hard functional block HFB. This can efficiently implement the systolic array SARY on the semiconductor device 100 by using the reconfiguration block RCB and the hard functional block HFB.

The processor may calculate the number of processing elements PE that can be mapped to the reconfiguration block RCB in advance before the first processing element PE is mapped to the reconfiguration block RCB. In this case, the processor first may divide the total number of LUTs (available LUTs) that can be used to map the processing elements PE in the vertical direction Y by the number y_PE of LUTs used to map the processing element PE in the vertical direction Y.

The processor then may obtain the maximum number of processing elements PE that can be mapped to the reconfiguration block RCB and the number of residual LUTs after mapping. The processor may repeat the division while changing the LUT number y_PE of the processing element PE until the number of residual LUTs becomes less than a predetermined number. This can obtain the mapping shape of the processing element PE that optimizes the implementation efficiency of the processing elements on the reconfiguration block RCB.

The processor may perform a process of calculating the number of processing elements PE that can be mapped to the reconfiguration block RCB while changing the mapping shape before step S206 of FIG. 11. Then, in step S206, the processor may determine whether the calculated number of processing elements PE has been mapped, may execute step S208, and then executes step S212. The processor may increase the number of mapped processing elements PE in step S210.

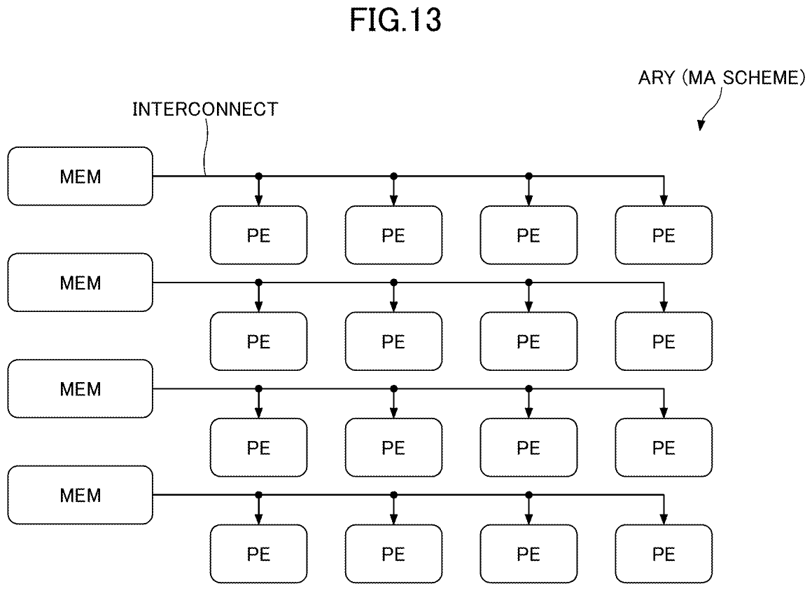

FIG. 13 is a block diagram illustrating an example (i.e., a comparative example) in which an array ARY of the processing elements PE including multipliers is implemented in an FPGA with LUTs, for example. In FIG. 13, the memory MEM may be provided for each row of the processing elements PE arranged in the horizontal direction X. Data retained in the memory may be transferred to each processing element PE through a common interconnect and used for an operation of each multiplier. If the common interconnect is used, the length of the interconnect may be limited to the length that satisfies the bandwidth. FIG. 13 is an implementation scheme suitable for an ASIC. The architecture illustrated in FIG. 13 is referred to as a multiplier array (MA) scheme.

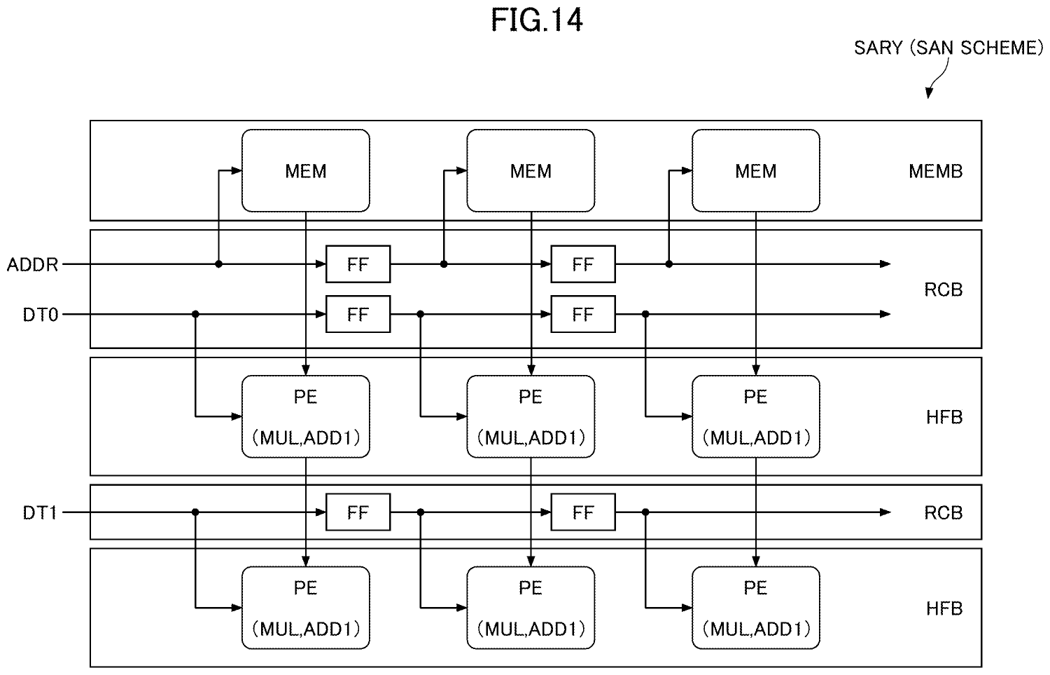

FIG. 14 is a block diagram illustrating an example (i.e., a comparative example) in which a systolic array SARY may be implemented in an FPGA in which the memory block MEMB, and the reconfiguration block RCB, and the hardware functional block HFB are repeatedly arranged.

The memory MEM may be implemented in the memory block MEMB, and the multiplier MUL and the adder ADD1 of the processing element PE may be implemented only in the hard functional block HFB. The elements other than the multiplier MUL and the adder ADD1 of the processing element PE may be implemented in the reconfiguration block RCB.

The reconfiguration block RCB of FIG. 14 may not include an interconnect INTC in which the interconnect registers ICREG are disposed at predetermined intervals. A register chain that transfers data and the like from the left to the right of FIG. 14 may be implemented in the reconfiguration block RCB. In the reconfiguration block RCB, many flip-flops FF for the register chain may be implemented, but the multiplier MUL and the adder ADD1 may not be implemented. Therefore, the implementation efficiency of the reconfiguration block RCB is lower than the implementation efficiency of the reconfiguration block RCB illustrated in FIG. 5. The architecture illustrated in FIG. 14 is commonly referred to as a systolic array (SAN) scheme.

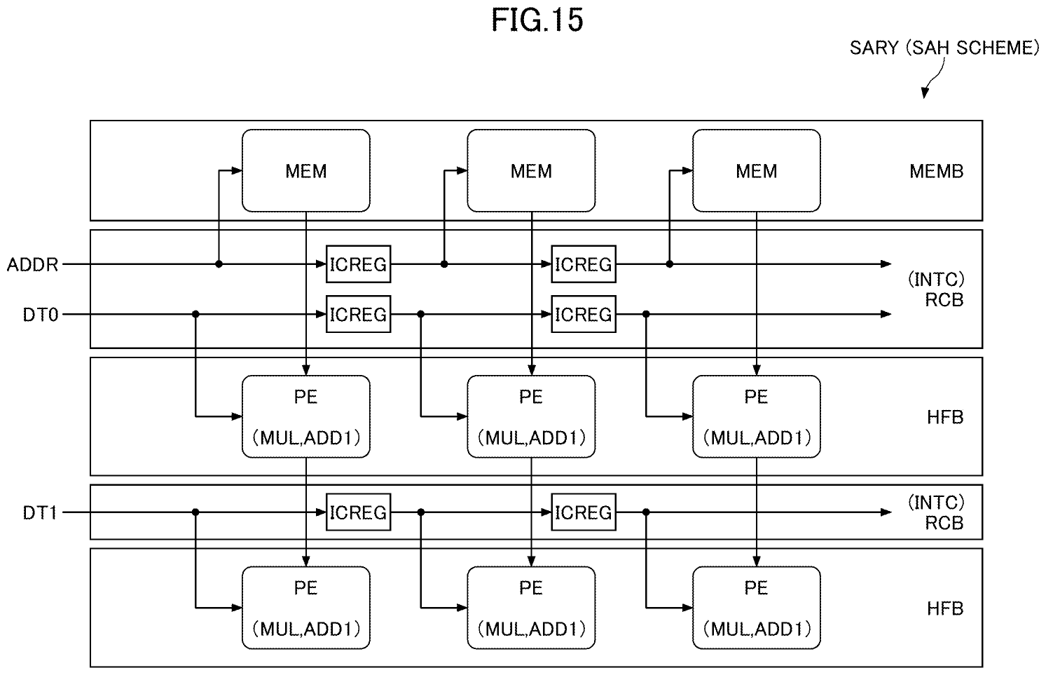

FIG. 15 is a block diagram illustrating an example (i.e., a comparative example) in which the systolic array SARY may be implemented in an FPGA in which the memory block MEMB, the reconfiguration block RCB, and the hardware functional block HFB may be repeatedly arranged. In the architecture illustrated in FIG. 15, the reconfiguration block RCB may include the interconnect INTC in which the interconnect registers ICREG may be disposed at predetermined intervals instead of the register chain illustrated in FIG. 14.

In FIG. 15, similarly with FIG. 14, because the multiplier MUL and the adder ADD1 may not be implemented in the reconfiguration block RCB, the implementation efficiency is lower than the implementation efficiency of the reconfiguration block RCB in FIG. 5. The architecture illustrated in FIG. 15 is referred to as a hyper-systolic array (SAH) scheme.

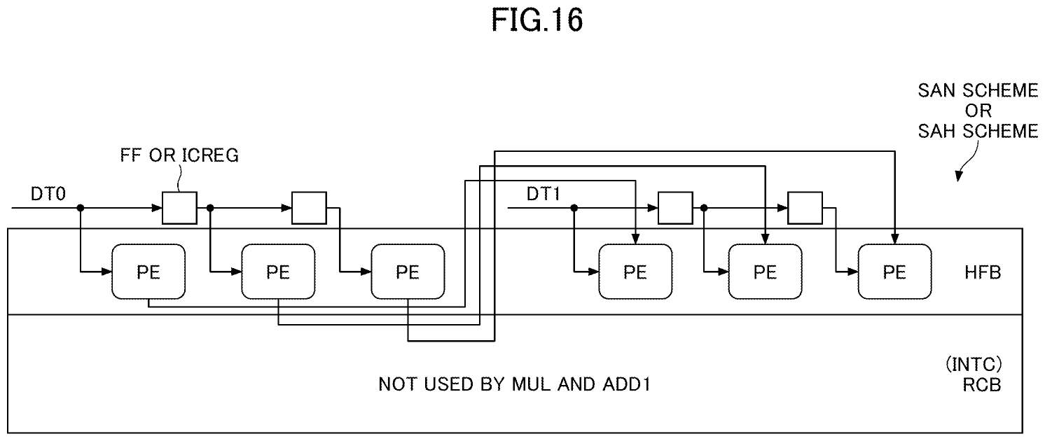

FIG. 16 is an explanatory diagram illustrating a problem to be solved when the processing elements PE are implemented in the semiconductor device with the architectures illustrated in FIG. 14 and FIG. 15. If the multiplier MUL and the adder ADD1 of the processing element PE are implemented using only the hard functional block HFB, the processing rows of the processing elements PE of the systolic array SARY may not be arranged in the vertical direction of FIG. 15.

In this case, the processing rows of the processing elements PE are arranged in the hard functional block HFB in the horizontal direction of FIG. 15. Therefore, as illustrated in FIG. 5, the interconnect between the processing rows of the processing elements PE is longer in comparison with a case in which the processing rows of the processing elements PE are arranged in the vertical direction. As a result, the transfer time of the weight and the partial sum between the processing elements PE that are logically arranged in the vertical direction is increased, and the bandwidth of the systolic array SARY is reduced. In this case, the characteristics of the systolic array SARY, in which a result of the convolution operation is efficiently transferred to the next processing element PE and the processing efficiency is improved, cannot be achieved.

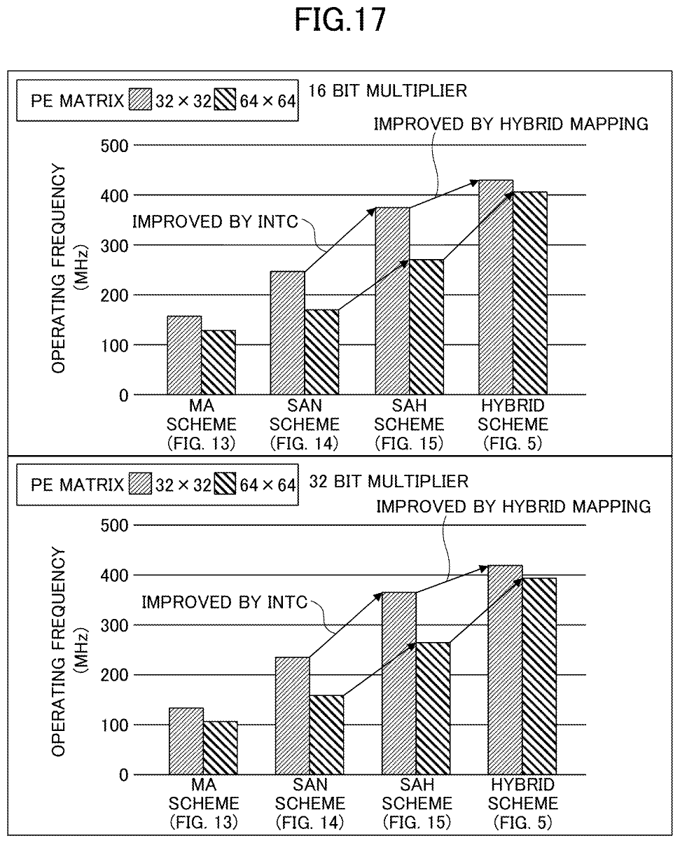

FIG. 17 is an explanatory diagram illustrating an example of operating frequencies respectively used when the array ARY or the systolic arrays SARY are implemented in the FPGAs according to the architectures illustrated in FIG. 5, FIG. 13, FIG. 14, and FIG. 15. The upper part of FIG. 17 illustrates respective operating frequencies of a PE matrix in which 32 processing elements PE are arranged vertically and horizontally using 16 bit multipliers and a PE matrix in which 64 processing elements PE are arranged vertically and horizontally using 16 bit multipliers. The lower part of FIG. 17 illustrates respective operating frequencies of a PE matrix in which 32 processing elements PE are arranged vertically and horizontally using 32 bit multipliers and a PE matrix in which 64 processing elements PE are arranged vertically and horizontally using 32 bit multipliers.

The SAH scheme can improve the operating frequency in comparison with the SAN scheme that does not include the interconnect INTC. However, the SAH scheme has the problem illustrated in FIG. 16 because the multiplier and the adder ADD1 of the processing element PE are mapped to only the hard functional block HFB.

In contrast, in the hybrid scheme having the architecture illustrated in FIG. 5, the multiplier and the adder ADD1 of the processing element PE are mapped to the hard functional block HFB and the reconfiguration block RCB. Therefore, there is no problem illustrated in FIG. 16, and the operating frequency can be improved in comparison with the SAH scheme.

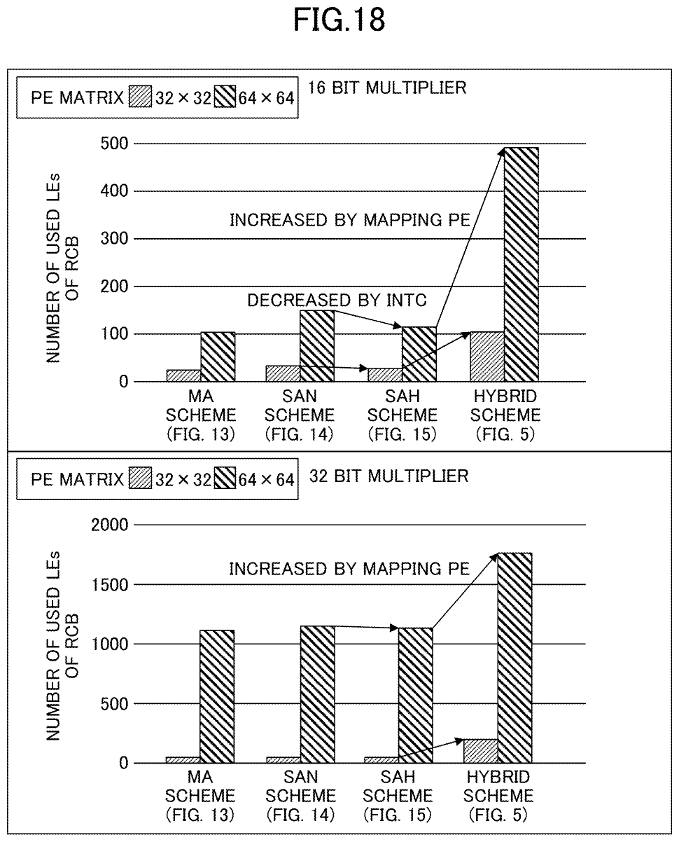

FIG. 18 is an explanatory diagram illustrating an example of the numbers of reconfiguration blocks RCB respectively used when the array ARY or the systolic arrays SARY are implemented in the FPGAs according to the architectures illustrated in FIGS. 5, 13, 14, and 15. Here, the usage amount of the reconfiguration blocks RCB is expressed as the number of used logic elements LE that is a basic unit in the reconfiguration block RCB. For elements substantially the same as the elements in FIG. 17, the detailed description will be omitted. The type of the used multiplier and the configuration of the PE matrix of the array ARY or the systolic array SARY are substantially the same as that of FIG. 17.

The SAH scheme reduces the number of used logic elements LE in comparison with the SAN scheme that does not have an interconnect INTC. The hybrid scheme can significantly increase the number of used logic elements LE because the multiplier and the adder ADD1 of the processing element PE are also mapped to the reconfiguration block RCB. As a result, the usage efficiency of the reconfiguration block RCB can be improved in comparison with the SAH scheme, and the implementation efficiency of the systolic array SARY on the FPGA can be improved.

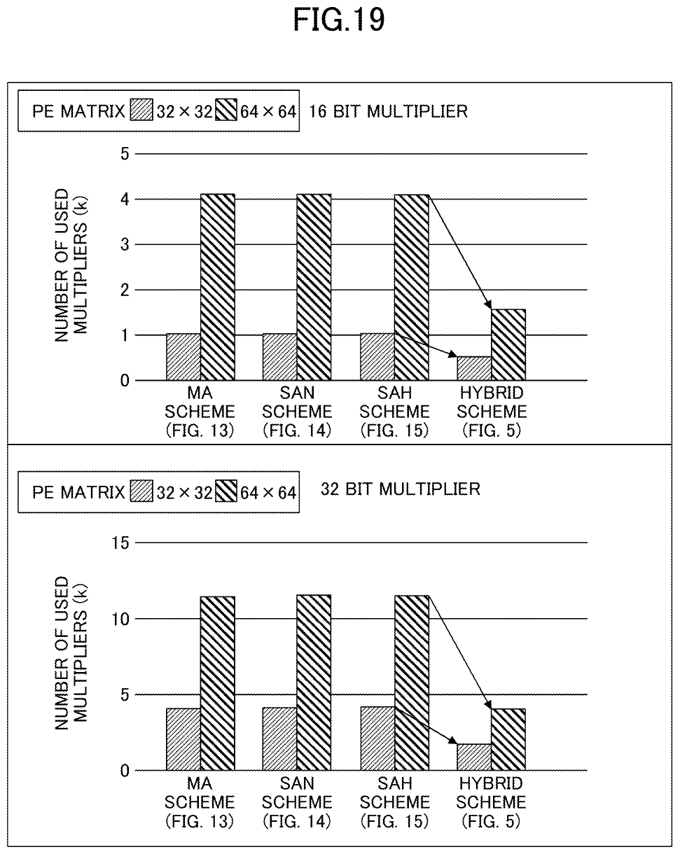

FIG. 19 is an explanatory diagram illustrating an example of the numbers of multipliers respectively used when the array ARY or the systolic arrays SARY are implemented in the FPGAs according to the architectures illustrated in FIGS. 5, 13, 14, and 15. For elements substantially the same as the elements in FIG. 17, the detailed description will be omitted. The type of the used multiplier and the configuration of the PE matrix of the array ARY or the systolic array SARY are substantially the same as that of FIG. 17.

The number of the used multipliers in the MA scheme is the number of the multipliers reconfigured using LUTs in the FPGA. The number of the used multipliers in the SAN scheme and the SAH scheme is the number of the multipliers disposed in the hard functional block HFB that are fixed circuits. Because each of the numbers of the used multipliers shown in the MA scheme, the SAN scheme, and the SAH scheme represents the number of all multipliers used by the array ARY or the systolic array SARY, the numbers are the same as one another.

With respect to the above, in the hybrid scheme, because the multipliers are mapped to the hard functional block HFB and the reconfiguration block RCB, the number of the multipliers used in the hard functional block HFB becomes less than the number of the used multipliers in the SAH scheme.

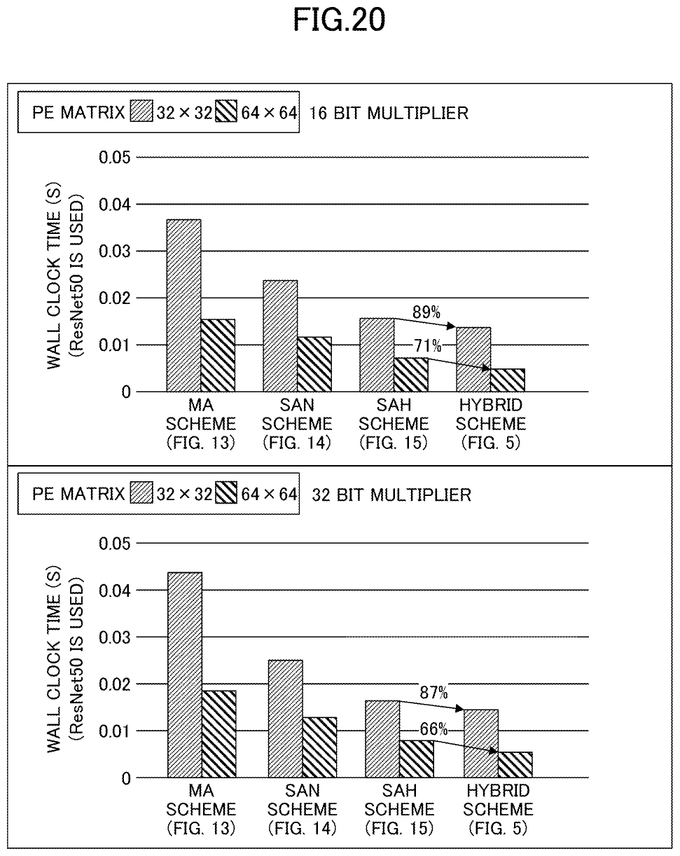

FIG. 20 is an explanatory diagram illustrating an example of the wall clock time respectively measured when the array ARY or the systolic arrays SARY are implemented in the FPGAs according to the architectures illustrated in FIG. 5, FIG. 13, FIG. 14, and FIG. 15. Residual Network 50 (ResNet50) is used as a model for neural network, although it is not particularly limited.

As shown in FIG. 20, the wall clock time of the SAH scheme and the hybrid scheme, which have a higher implementation efficiency, is shorter than the wall clock time of the MA scheme and the SAN scheme. The wall clock time of the hybrid scheme having the highest implementation efficiency of the processing element PE merely requires about 70% to 90% of the wall clock time of the SAH scheme.

As described above, when the systolic array SARY is implemented in the semiconductor device 100 having the structure illustrated in FIG. 1, the bandwidth can be improved and the processing performance can be improved by adopting the hybrid method, compared to the other schemes. In other words, in addition to adopting the interconnect INTC, mapping the multipliers to the hard functional block HFB and the reconfiguration block RCB can maximize the bandwidth and the processing performance.

Each device (i.e., the FPGA tool or a device 200 illustrated in FIG. 21) according to the present embodiment may be partially or entirely configured by hardware or may be configured by information processing of software (i.e., a program) executed by a processor, such as a CPU or a graphics processing unit (GPU). If the device is configured by the information processing of software, the information processing of software may be performed by storing the software that achieves at least a portion of a function of each device according to the present embodiment in a non-transitory storage medium (i.e., a non-transitory computer-readable medium), such as a flexible disk, a compact disc-read only memory (CD-ROM), or a universal serial bus (USB) memory, and causing a computer to read the software. The software may also be downloaded through a communication network. Additionally, the information processing may be performed by the hardware by implementing software in a circuit such as an application specific integrated circuit (ASIC) or an FPGA.

The type of the storage medium storing the software is not limited. The storage medium is not limited to a removable storage medium, such as a magnetic disk or an optical disk, but may be a fixed storage medium, such as a hard disk or a memory. The storage medium may be provided inside the computer or outside the computer.

FIG. 21 is a block diagram illustrating an example of a hardware configuration of the device 200 that maps the systolic array SARY of FIG. 2 to the semiconductor device 100 of FIG. 1. The device 200 includes, for example, a processor 210, a main storage device (i.e., a main memory) 220, an auxiliary storage device (i.e., an auxiliary memory) 230, a network interface 240, and a device interface 250. The device 200 may be implemented as a computer (i.e., an information processing device such as a server) in which these components are connected through a bus 260. For example, when the processor 210 executes a circuit layout program, the process described in FIGS. 9 to 12 are performed, and the device 200 operates as the FPGA tool.

The device 200 includes one of each component, but may also include multiple units of the same component. Additionally, although one device 200 is illustrated in FIG. 21, the software may be installed on multiple devices including the device 200 and each of the multiple devices 200 may perform the same process of the software or a different part of the process of the software. In this case, each of the devices 200 may communicate with one another through the network interface 240 or the like to perform the process in a form of distributed computing. That is, the device that maps the systolic array SARY of FIG. 2 to the semiconductor device 100 of FIG. 1 may be configured as a computer system that achieves the function by causing one or more devices 200 to execute instructions stored in one or more storage devices. The device may also be configured as a system in which one or more devices 200 provided on the cloud process information transmitted from a terminal and then transmit a processed result to the terminal.

The process described in FIGS. 9 to 12 may be performed in parallel by using one or more processors 210 or using multiple computers connected through the communication network 300. Various operations may be distributed to multiple arithmetic cores in the processor 210 and may be performed in parallel. At least one of a processor or a storage device provided on a cloud that can communicate with the device 200 through a network may be used to perform some or all of the processes, means, and the like of the present disclosure. As described, a computer system including the device 200 may be in a form of parallel computing system including one or more computers.

The processor 210 may be an electronic circuit including a computer controller and a computing device (such as a processing circuit, a CPU, a GPU, an FPGA, or an ASIC). The processor 210 may be a semiconductor device or the like that includes a dedicated processing circuit. The processor 210 is not limited to an electronic circuit using electronic logic elements, but may be implemented by an optical circuit using optical logic elements. The processor 210 may also include a computing function based on quantum computing.

The processor 210 can perform arithmetic processing based on data or software (i.e., a program) input from each device or the like in the internal configuration of the device 200 and output an arithmetic result or a control signal to each device. The processor 210 may control respective components constituting the device 200 by executing an operating system (OS) of the device 200, an application, or the like.

The device 200 may be implemented by one or more processors 210. Here, the processor 210 may refer to one or more electronic circuits disposed on one chip or may refer to one or more electronic circuits disposed on two or more chips or two or more devices. If multiple electronic circuits are used, each electronic circuit may communicate by wire or wireless.

The main storage device 220 is a storage device that stores instructions executed by the processor 210 and various data. The information stored in the main storage device 220 is read by the processor 210. The auxiliary storage device 230 is a storage device other than the main storage device 220. These storage devices indicate any electronic component that can store electronic information and may be semiconductor memories. The semiconductor memory may be either a volatile memory or a non-volatile memory. The storage device for storing various data in the device 200 may be implemented by the main storage device 220 or the auxiliary storage device 230, or may be implemented by an internal memory embedded in the processor 210. For example, various parameters used in the processes described in FIGS. 9 to 12 may be stored in the main storage device 220 or the auxiliary storage device 230.

The device 200 is not limited to the configuration illustrated in FIG. 21. To a single storage device (i.e., one memory), multiple processors may be connected (or coupled) or a single processor may be connected. To a single processor, multiple storage devices (i.e., multiple memories) may be connected (or coupled). If the device 200 includes at least one storage device (i.e., one memory) and multiple processors connected (or coupled) to the at least one storage device (i.e., one memory), at least one of the multiple processors may be connected to the at least one storage device (i.e., one memory). This configuration may be implemented by the storage devices (i.e., memories) and the processors included in the multiple devices 200. Further, the storage device (i.e., the memory) may be integrated with the processor (e.g., a cache memory including an L1 cache and an L2 cache).

The network interface 240 is an interface for connecting to the communication network 300 by wireless or wire. As the network interface 240, any suitable interface, such as an interface conforming to existing communication standards, may be used. The network interface 240 may exchange information with an external device 310 connected through the communication network 300. The communication network 300 may be any one of a wide area network (WAN), a local area network (LAN), a personal area network (PAN), or a combination thereof, in which information is exchanged between the device 200 and the external device 310. Examples of the WAN include the Internet, examples of the LAN include IEEE 802.11 and Ethernet (registered trademark), and examples of the PAN include Bluetooth (registered trademark) and near field communication (NFC).

The device interface 250 is an interface, such as a USB, that directly connects to an external device 320.

The external device 320 may be connected to the device 200 through a network or may be directly connected to the device 200.

The external device 310 or the external device 320 may be, for example, an input device. The input device may be, for example, a camera, a microphone, a motion capture, various sensors, a keyboard, a mouse, or a touch panel or the like, and provides obtained information to the device 200. The input device may also be a device including an input unit, a memory, and a processor, such as a personal computer, a tablet terminal, or a smartphone.

The external device 310 or the external device 320 may be, for example, an output device. The output device may be, for example, a display device, such as a liquid crystal display (LCD), a cathode-ray tube (CRT), a plasma display panel (PDP), or an organic electro luminescence (EL) panel, or may be a speaker or the like that outputs the voice. The output device may also be a device including an output unit, a memory, and a processor, such as a personal computer, a tablet terminal, or a smartphone.

The external device 310 or the external device 320 may be a storage device (i.e., a memory). For example, the external device 310 may be a storage such as a network storage, and the external device 320 may be a storage such as an HDD. The external device 320 that is a storage device (i.e., a memory), is an example of a storage medium that can be read by a computer such as the processor 210.

The external device 310 or the external device 320 may be a device having functions of some of the components of the device 200. That is, the device 200 may transmit or receive some or all of processed results of the external device 310 or the external device 320.

In this embodiment, an arithmetic unit in the processing element PE can be implemented in either the reconfiguration block RCB or the hard functional block HFB, in accordance with a position of the processing element PE in the systolic array SARY. That is, it can be selected whether all elements of the processing element PE are implemented in the reconfiguration block RCB or only logic circuits are implemented in the reconfiguration block RCB.

As a result, the usage efficiency of the reconfiguration block RCB can be improved and the implementation efficiency of the systolic array SARY to the semiconductor device 100 can be improved. In particular, the usage efficiency of the LUTs of the reconfiguration block RCB can be improved. By improving the usage efficiency and the implementation efficiency, the performance such as the operating frequency of the systolic array SARY can be improved and a time period required for training a neural network or required for performing inference can be reduced.

The interconnect INTC can transfer a control signal and data to each processing element PE in accordance with the processing speed of each processing element PE, thereby improving the performance of the systolic array SARY.

In accordance with the LUT usage amount of the reconfiguration block RCB, the reconfiguration block RCB to which the processing element PE and the accumulator ACM are mapped can be changed. In accordance with the LUT usage amount of the reconfiguration block RCB, the adder ADD2 of the accumulator ACM can also be mapped to either the reconfiguration block RCB or the hard functional block HFB. This can minimize transmission delays of data or the like between the processing elements PE and between the processing element PE and the accumulator ACM, thereby improving the processing efficiency (i.e., the processing speed and the bandwidth) of the systolic array SARY.

By implementing the accumulator controller 30 near the accumulator ACM, the length of a control signal line connecting the accumulator controller 30 and each accumulator ACM can be minimized. This prevents a delay of a control of each accumulator ACM.

By implementing the weight memory W near the processing element PE to which the weight is input, the length of a transfer path of the weight from each weight memory W to a corresponding processing element PE can be minimized, and the transfer time of the weight can be minimized. By implementing the output memory unit 80 near the accumulator ACM, the length of a transfer path of the output data from the accumulator ACM to the output memory OUT can be minimized, and the transfer time of the output data can be minimized.

By implementing the internal memory IMEM near the processing element PE, the length of a transfer path of an instruction and data from each internal memory IMEM to a corresponding processing element PE can be minimized, and the transfer time of an instruction and data can be minimized.

By implementing the memory controller 10 in a reconfiguration block RCB adjacent to the memory block MEMB in which the internal memory IMEM and the weight memory W are implemented, an increase of the access time of the internal memory IMEM and the weight memory W can be prevented. Similarly, by implementing the memory controller 40 to a reconfiguration block RCB adjacent to the memory block MEMB in which the output memory OUT is implemented, an increase of the access time of the output memory OUT can be prevented.

If there is not sufficient free space in the vertical direction Y of the reconfiguration block RCB, the processing element PE can be arranged in the reconfiguration block RCB by changing a layout form of the processing element PE if a predetermined condition is satisfied. This can improve the usage efficiency of the LUTs in the reconfiguration block RCB and improve the implementation efficiency of the systolic array SARY to the semiconductor device 100.

In the present specification (including the claims), if the expression “at least one of a, b, and c” or “at least one of a, b, or c” is used (including similar expressions), any one of a, b, c, a-b, a-c, b-c, or a-b-c is included. Multiple instances may also be included in any of the elements, such as a-a, a-b-b, and a-a-b-b-c-c. Further, the addition of another element other than the listed elements (i.e., a, b, and c), such as adding d as a-b-c-d, is included.

In the present specification (including the claims), if the expression such as “data as an input”, “based on data”, “according to data”, or “in accordance with data” (including similar expressions) is used, unless otherwise noted, a case in which various data itself is used as an input and a case in which data obtained by processing various data (e.g., data obtained by adding noise, normalized data, and intermediate representation of various data) is used as an input are included. If it is described that any result can be obtained “based on data”, “according to data”, or “in accordance with data”, a case in which a result is obtained based on only the data is included, and a case in which a result is obtained affected by another data other than the data, factors, conditions, and/or states may be included. If it is described that “data is output”, unless otherwise noted, a case in which various data is used as an output is included, and a case in which data processed in some way (e.g., data obtained by adding noise, normalized data, and intermediate representation of various data) is used as an output is included.

In the present specification (including the claims), if the terms “connected” and “coupled” are used, the terms are intended as non-limiting terms that include any of direct, indirect, electrically, communicatively, operatively, and physically connected/coupled. Such terms should be interpreted according to a context in which the terms are used, but a connected/coupled form that is not intentionally or naturally excluded should be interpreted as being included in the terms without being limited.

In the present specification (including the claims), if the expression “A configured to B” is used, a case in which a physical structure of the element A has a configuration that can perform the operation B, and a permanent or temporary setting/configuration of the element A is configured/set to actually perform the operation B may be included. For example, if the element A is a general purpose processor, the processor may have a hardware configuration that can perform the operation B and be configured to actually perform the operation B by setting a permanent or temporarily program (i.e., an instruction). If the element A is a dedicated processor or a dedicated arithmetic circuit, a circuit structure of the processor may be implemented so as to actually perform the operation B irrespective of whether the control instruction and the data are actually attached.

In the present specification (including the claims), if a term indicating containing or possessing (e.g., “comprising/including” and “having”) is used, the term is intended as an open-ended term, including an inclusion or possession of an object other than a target object indicated by the object of the term. If the object of the term indicating an inclusion or possession is an expression that does not specify a quantity or that suggests a singular number (i.e., an expression using “a” or “an” as an article), the expression should be interpreted as being not limited to a specified number.

In the present specification (including the claims), even if an expression such as “one or more” or “at least one” is used in a certain description, and an expression that does not specify a quantity or that suggests a singular number is used in another description (i.e., an expression using “a” or “an” as an article), it is not intended that the latter expression indicates “one”. Generally, an expression that does not specify a quantity or that suggests a singular number (i.e., an expression using “a” or “an” as an article) should be interpreted as being not necessarily limited to a particular number.

In the present specification, if it is described that a particular advantage/result is obtained in a particular configuration included in an embodiment, unless there is a particular reason, it should be understood that that the advantage/result may be obtained in another embodiment or other embodiments including the configuration. It should be understood, however, that the presence or absence of the advantage/result generally depends on various factors, conditions, states, and/or the like, and that the advantage/result is not necessarily obtained by the configuration. The advantage/result is merely an advantage/result that results from the configuration described in the embodiment when various factors, conditions, states, and/or the like are satisfied, and is not necessarily obtained in the claimed invention that defines the configuration or a similar configuration.

In the present specification (including the claims), if a term such as “maximize” is used, it should be interpreted as appropriate according to a context in which the term is used, including obtaining a global maximum value, obtaining an approximate global maximum value, obtaining a local maximum value, and obtaining an approximate local maximum value. It also includes determining approximate values of these maximum values, stochastically or heuristically. Similarly, if a term such as “minimize” is used, they should be interpreted as appropriate, according to a context in which the term is used, including obtaining a global minimum value, obtaining an approximate global minimum value, obtaining a local minimum value, and obtaining an approximate local minimum value. It also includes determining approximate values of these minimum values, stochastically or heuristically. Similarly, if a term such as “optimize” is used, the term should be interpreted as appropriate, according to a context in which the term is used, including obtaining a global optimum value, obtaining an approximate global optimum value, obtaining a local optimum value, and obtaining an approximate local optimum value. It also includes determining approximate values of these optimum values, stochastically or heuristically.

In the present specification (including the claims), if multiple hardware performs predetermined processes, each of the hardware may cooperate to perform the predetermined processes, or some of the hardware may perform all of the predetermined processes. Additionally, some of the hardware may perform some of the predetermined processes while another hardware may perform the remainder of the predetermined processes. In the present specification (including the claims), if an expression such as “one or more hardware perform a first process and the one or more hardware perform a second process” is used, the hardware that performs the first process may be the same as or different from the hardware that performs the second process. That is, the hardware that performs the first process and the hardware that performs the second process may be included in the one or more hardware. The hardware may include an electronic circuit, a device including an electronic circuit, or the like.

In the present specification (including the claims), if multiple storage devices (memories) store data, each of the multiple storage devices (memories) may store only a portion of the data or may store an entirety of the data.

Although the embodiments of the present disclosure have been described in detail above, the present disclosure is not limited to the individual embodiments described above. Various additions, modifications, substitutions, partial deletions, and the like may be made without departing from the conceptual idea and spirit of the invention derived from the contents defined in the claims and the equivalents thereof. For example, in all of the embodiments described above, if numerical values or mathematical expressions are used for description, they are presented as an example and are not limited thereto. Additionally, the order of respective operations in the embodiment is presented as an example and is not limited thereto.

What is claimed is:

1. A semiconductor device comprising:
a plurality of reconfiguration blocks arranged in a first direction, logic of the plurality of reconfiguration blocks being reconfigurable;
a plurality of non-reconfiguration blocks disposed between the plurality of reconfiguration blocks, each of the plurality of non-reconfiguration blocks including a plurality of first arithmetic units, and logic of the plurality of first arithmetic units being not reconfigurable; and
a plurality of processing units implemented in the plurality of reconfiguration blocks and the plurality of non-reconfiguration blocks in a form of a matrix, the plurality of processing units including second arithmetic units, wherein, for each of a plurality of processing rows, the second arithmetic units are implemented using either the first arithmetic units of a corresponding one of the non-reconfiguration blocks or a corresponding one of the reconfiguration blocks, each of the plurality of processing rows being a row in which a predetermined number of processing units among the plurality of processing units are arranged in a second direction crossing the first direction.

2. The semiconductor device as claimed in claim 1,
wherein the plurality of processing rows include a first processing row and a second processing row different from the first processing row, and
wherein the second arithmetic units in the first processing row are implemented using the first arithmetic units of a non-reconfiguration block corresponding to the first processing row and the second arithmetic units in the second processing row are implemented using a reconfiguration block corresponding to the second processing row.

3. The semiconductor device as claimed in claim 1, further comprising an interconnect disposed along the second direction in each of the reconfiguration blocks, a predetermined number of latch circuits being selectively inserted in the interconnect, and the interconnect sequentially transferring signals to the predetermined number of processing units in a processing row implemented using a corresponding one of the reconfiguration blocks.

4. The semiconductor device as claimed in claim 1, wherein the plurality of processing units include first logic circuits, and the first logic circuits in a given processing row are implemented in a reconfiguration block that is adjacent to a non-reconfiguration block in which the second arithmetic units in the given processing row are implemented.

5. The semiconductor device as claimed in claim 1, further comprising an accumulator connected to a last processing row of the plurality of processing rows, the accumulator accumulating arithmetic results of the plurality of processing rows, wherein second logic circuits included in the accumulator are implemented in a reconfiguration block that implements the last processing row of the plurality of processing rows, or are implemented in a reconfiguration block subsequent to the reconfiguration block that implements the last processing row.

6. The semiconductor device as claimed in claim 5, wherein a third arithmetic unit included in the accumulator is implemented in the reconfiguration block that implements the second logic circuits, or is implemented in a non-reconfiguration block adjacent to the reconfiguration block that implements the second logic circuits.

7. The semiconductor device as claimed in claim 5, further comprising a controller that controls an operation of the accumulator, wherein the controller is implemented in the reconfiguration block that implements the accumulator.

8. The semiconductor device as claimed in claim 1, further comprising a plurality of memory blocks arranged in the first direction, the plurality of memory blocks being adjacent to the plurality of reconfiguration blocks or adjacent to the plurality of non-reconfiguration blocks;
an input memory storing input data input to a given processing unit among the plurality of processing units; and
an output memory storing output data output from a given processing unit among the plurality of processing units;
wherein the input memory is implemented in a memory block adjacent to a reconfiguration block that implements the given processing unit to which the input data is input; and
wherein the output memory is implemented in a memory block adjacent to a reconfiguration block that implements the given processing unit from which the output data is output.

9. The semiconductor device as claimed in claim 8, further comprising:
an input memory controller that controls an operation of the input memory; and
an output memory controller that controls an operation of the output memory;
wherein the input memory controller is implemented in a reconfiguration block adjacent to the memory block that implements the input memory; and
wherein the output memory controller is implemented in a reconfiguration block adjacent to the memory block that implements the output memory.

10. A circuit layout method for arranging,
in a semiconductor device including a plurality of reconfiguration blocks arranged in a first direction, logic of the plurality of reconfiguration blocks being reconfigurable, and a plurality of non-reconfiguration blocks disposed between the plurality of reconfiguration blocks, each of the plurality of non-reconfiguration blocks including a plurality of first arithmetic units, and logic of the plurality of first arithmetic units being not reconfigurable,
a plurality of processing units arranged in the plurality of reconfiguration blocks and the plurality of non-reconfiguration blocks in a form of a matrix, the plurality of processing units including second arithmetic units,
the method comprising arranging, for each of a plurality of processing rows, the second arithmetic units by using either the first arithmetic units of a corresponding one of the non-reconfiguration blocks or a corresponding one of the reconfiguration blocks, each of the plurality of processing rows being a row in which a predetermined number of processing units among the plurality of processing units are arranged in a second direction crossing the first direction.

11. The circuit layout method as claimed in claim 10, the method further comprising determining whether the plurality of processing units can be arranged in the plurality of reconfiguration blocks based on a size of each of the plurality of processing units, in the first direction, required when each of the plurality of processing units is arranged in a corresponding one of the reconfiguration blocks and based on a size of a portion of each of the plurality of reconfiguration blocks, in the first direction, that can be used to arrange a corresponding one of the plurality of processing units.

12. The circuit layout method as claimed in claim 11, wherein each of the plurality of reconfiguration blocks includes a plurality of lookup tables arranged in a form of a matrix, and the size of each of the plurality of processing units in the first direction and the size of the portion of each of the plurality of reconfiguration blocks, in the first direction, that can be used to arrange the corresponding one of the plurality of processing units are calculated based on a number of the lookup tables arranged in the first direction.

13. The circuit layout method as claimed in claim 12, the method further comprising
increasing a number of the lookup tables, in the second direction, that are used to arrange processing units in each of the processing rows, decreasing a number of the lookup tables, in the first direction, that are used to arrange the processing units in each of the processing rows, and rearranging the plurality of processing rows in the plurality of reconfiguration blocks, in a case where, after arranging processing units in a given processing row, a number Ya of available lookup tables in the first direction that can be used to arrange processing units in a remaining processing row is less than a number Yb of the lookup tables, in the first direction, used to arrange each of the plurality of processing units in conjunction with a case where a ratio Ya/Yb is greater than or equal to a predetermined value.

14. The circuit layout method as claimed in claim 10, wherein the plurality of processing units include first logic circuits, and the method further comprises arranging the first logic circuits in a given processing row in a reconfiguration block that is adjacent to a non-reconfiguration block in which the second arithmetic units in the given processing row are arranged.

15. The circuit layout method as claimed in claim 10, the method further comprising arranging a second logic circuit included in an accumulator in a reconfiguration block in which a last processing row of the plurality of processing rows is arranged, or in a reconfiguration block subsequent to the reconfiguration block in which the last processing row is arranged, the accumulator being connected to the last processing row of the plurality of processing rows, and the accumulator accumulating arithmetic results of the plurality of processing rows.

16. The circuit layout method as claimed in claim 15, the method further comprising arranging a third arithmetic unit included in the accumulator in a reconfiguration block in which the second logic circuits are arranged, or in a non-reconfiguration block adjacent to the reconfiguration block in which the second logic circuits are arranged.

17. The circuit layout method as claimed in claim 10, wherein an interconnect is disposed along the second direction in each of the reconfiguration blocks.

18. The circuit layout method as claimed in claim 17, wherein a predetermined number of latch circuits are selectively inserted in the interconnect, and the interconnect sequentially transfers signals to the predetermined number of processing units in a processing row implemented using a corresponding one of the reconfiguration blocks.

19. The circuit layout method as claimed in claim 10, wherein a plurality of memory blocks are arranged in the first direction, and the plurality of memory blocks are adjacent to the plurality of reconfiguration blocks or adjacent to the plurality of non-reconfiguration blocks.

20. A non-transitory computer-readable recording medium having stored therein a program for arranging, in a semiconductor device including a plurality of reconfiguration blocks arranged in a first direction, logic of the reconfiguration blocks being reconfigurable, and a plurality of non-reconfiguration blocks disposed between the plurality of reconfiguration blocks, each of the non-reconfiguration blocks including a plurality of first arithmetic units, and logic of the plurality of first arithmetic units being not reconfigurable, a plurality of processing units implemented in a form of a matrix, the plurality of processing units including second arithmetic units, the program causing a computer to execute a process comprising arranging, for each of a plurality of processing rows, the second arithmetic units by using either the first arithmetic units of a corresponding one of the non-reconfiguration blocks or a corresponding one of the reconfiguration blocks, each of the plurality of processing rows being a row in which a predetermined number of processing units among the plurality of processing units are arranged in a second direction crossing the first direction.
